(19) United States
(12) Patent Application Publication
(10) Pub. No.: US 2025/0294755 A1
(43) Pub. Date: Sep. 18, 2025

(54) MEMORY DEVICE

(71) Applicant: Kioxia Corporation, Tokyo (JP)

(72) Inventors: Hiromi TAKAHASHI, Kuwana Mie (JP); Kazuhiro NOJIMA, Mie Mie (JP)

(21) Appl. No.: 19/026,015

(22) Filed: Jan. 16, 2025

(30) Foreign Application Priority Data
Mar. 18, 2024 (JP) 2024-042705

(51) Int. Cl. H10B 43/27; G11C 16/26; H10B 43/10

(52) U.S. Cl. CPC H10B 43/27; H10B 43/10; G11C 16/26

(57) ABSTRACT

A memory device includes a substrate, a plurality of conductive layers arranged in a first direction above the substrate, a plurality of pillars, each of which extends along the first direction and intersects with the conductive layers, a memory cell being formed at an intersection of one of the pillars and one of the conductive layers, and a plurality of first contacts each extending along the first direction and electrically connected to a corresponding one of the conductive layers. Each of the first contacts includes a first conductive member extending along the first direction, a first connection portion in contact with a side surface of the first conductive member and the corresponding conductive layer to electrically connect the first conductive member to the corresponding conductive layer, and a first insulating film surrounding the side surface of the first conductive member except at a location of the first connection portion.

### CROSS-REFERENCE TO RELATED APPLICATION

This application is based upon and claims the benefit of priority from Japanese Patent Application No. 2024-042705, filed Mar. 18, 2024, the entire contents of which are incorporated herein by reference.

### FIELD

Embodiments described herein relate generally to a memory device.

### BACKGROUND

A NAND flash memory capable of storing data in a non-volatile manner is known.

### BRIEF DESCRIPTION OF THE DRAWINGS

FIG. 1 is a block diagram showing an overall configuration of a memory system including a memory device according to an embodiment.

FIG. 2 is a circuit diagram showing a circuit configuration of a memory cell array provided in the memory device.

FIG. 3 is a perspective view showing an appearance of the memory device.

FIG. 4 is a plan view showing a planar layout of the memory cell array provided in the memory device.

FIG. 5 is a cross-sectional view showing a cross-sectional structure in a memory area of the memory cell array provided in the memory device.

FIG. 6 is a cross-sectional view taken along line VI-VI in FIG. 5, showing a cross-sectional structure of a memory pillar provided in the memory device.

FIG. 7 is a cross-sectional view showing a cross-sectional structure in a contact area and a PN contact area of the memory cell array provided in the memory device.

FIG. 8 is a cross-sectional view taken along line VIII-VIII in FIG. 7, showing a cross-sectional structure of a contact before conduction, which is provided in the memory device.

FIG. 9 is a cross-sectional view taken along line IX-IX in FIG. 7, showing a cross-sectional structure of a PN contact provided in the memory device.

FIG. 10 is a cross-sectional view showing a cross-sectional structure of the memory device.

FIG. 11 is a cross-sectional view taken along line XI-XI in FIG. 10, showing a cross-sectional structure of a contact after conduction, which is provided in the memory device.

FIG. 12 is a cross-sectional view showing a cross-sectional structure during a manufacturing process of the memory cell array provided in the memory device.

FIG. 13 is a cross-sectional view showing a cross-sectional structure during a manufacturing process of the memory cell array provided in the memory device.

FIG. 14 is a cross-sectional view showing a cross-sectional structure during a manufacturing process of the memory cell array provided in the memory device.

FIG. 15 is a cross-sectional view showing a cross-sectional structure during a manufacturing process of the memory cell array provided in the memory device.

FIG. 16 is a cross-sectional view showing a cross-sectional structure during a manufacturing process of the memory cell array provided in the memory device.

FIG. 17 is a cross-sectional view showing a cross-sectional structure during a manufacturing process of the memory cell array provided in the memory device.

FIG. 18 is a cross-sectional view showing a cross-sectional structure during a manufacturing process of the memory cell array provided in the memory device.

FIG. 19 is a cross-sectional view showing a cross-sectional structure during a manufacturing process of the memory cell array provided in the memory device.

FIG. 20 is a flowchart showing a conduction method between a stacked wiring and a contact provided in the memory device.

FIG. 21 is a schematic view showing a conduction process between a stacked wiring and contacts provided in the memory device.

FIG. 22 is a schematic view showing a conduction process between a stacked wiring and contacts provided in the memory device.

FIG. 23 is a schematic view showing a conduction process between a stacked wiring and contacts provided in the memory device.

FIG. 24 is a schematic view showing voltages applied to a stacked wiring, a contact, and a PN contact in a read operation of the memory device.

FIG. 25 is a cross-sectional view showing a cross-sectional structure in a contact area of a memory cell array according to a first modification example.

FIG. 26 is a cross-sectional view showing a cross-sectional structure in a contact area and a PN contact area of a memory cell array according to a second modification example.

FIG. 27 is a cross-sectional view showing a cross-sectional structure of a memory device according to a third modification example.

FIG. 28 is a cross-sectional view showing a cross-sectional structure of a memory device according to a fourth modification example.

FIG. 29 is a cross-sectional view showing a cross-sectional structure of a memory device according to a fifth modification example.

FIG. 30 is a cross-sectional view showing a detailed cross-sectional structure of a memory pillar at a boundary portion between two tiers provided in the memory device according to the fifth modification example.

FIG. 31 is a cross-sectional view showing a detailed cross-sectional structure of the vicinity of two bonding pads disposed opposite to each other in a memory device according to an embodiment.

### DETAILED DESCRIPTION

In general, according to one embodiment, a memory device comprises a substrate; a plurality of conductive layers arranged in a first direction above the substrate; a plurality of pillars, each of which extends along the first direction and intersects with the conductive layers, wherein a memory cell is formed at an intersection of one of the pillars and one of the conductive layers; and a plurality of first contacts each extending along the first direction and electrically connected to a corresponding one of the conductive layers. Each of the first contacts includes: a first conductive member extending along the first direction, a first connection portion in contact with a side surface of the first conductive member and the corresponding conductive layer to electrically connect the first conductive member to the corresponding conductive layer, and a first insulating film surrounding the side surface of the first conductive member except at a location of the first connection portion.

Hereinafter, embodiments will be described with reference to the drawings. The embodiments illustrate a device or a method for embodying the technical scope of the disclosure. The hatches added to the plan view of the drawings are not necessarily related to the materials and properties of the elements. In this specification, the same reference numerals are added to the elements having substantially the same function and configuration. Numbers, characters, and the like added to the reference code are referenced by the same reference code and are used to distinguish between similar elements.

### <1> Configuration

First, a configuration of a memory device 1 according to an embodiment will be described.

### <1-1> Overall Configuration of Memory Device 1

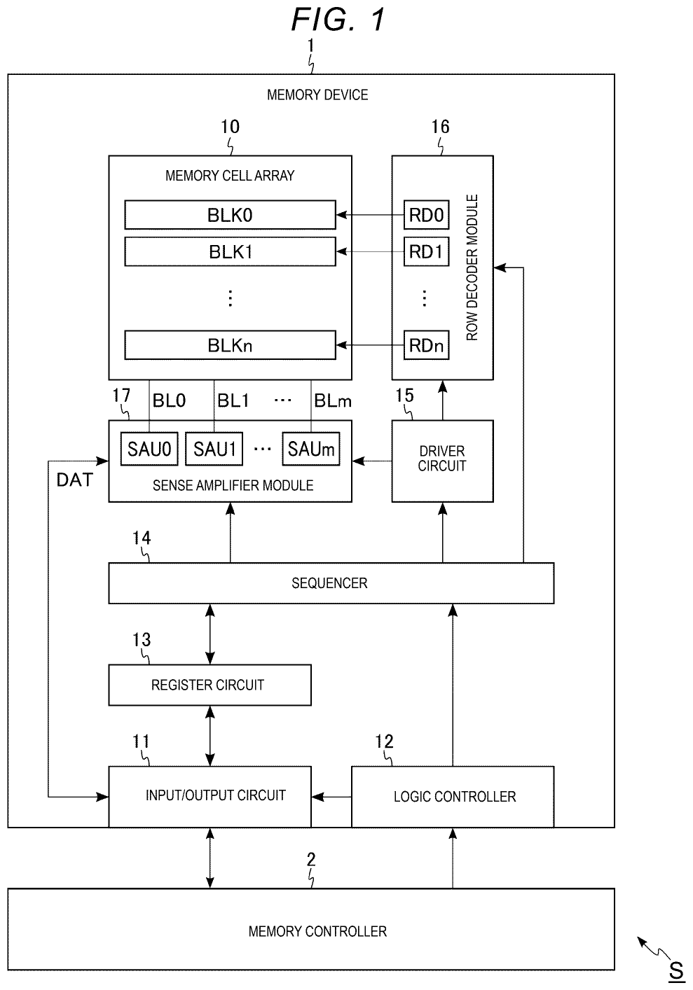

FIG. 1 is a block diagram showing an overall configuration of a memory system S including the memory device 1 according to an embodiment. As shown in FIG. 1, the memory device 1 is controlled by an external memory controller 2. The memory device 1 is, for example, a NAND flash memory capable of storing data in a non-volatile manner. The memory device 1 includes, for example, a memory cell array 10, an input/output circuit 11, a logic controller 12, a register circuit 13, a sequencer 14, a driver circuit 15, a row decoder module 16, and a sense amplifier module 17.

The memory cell array 10 includes a plurality of blocks BLK0 to BLKn (“n” is an integer equal to or greater than 1). The block BLK is a set of a plurality of memory cells. The block BLK corresponds to, for example, a unit of data erasure. The block BLK includes a plurality of pages. The page corresponds to a unit in which data is read and written. Although not shown, the memory cell array 10 is provided with a plurality of bit lines BL0 to BLm (where “m” is an integer equal to or greater than 1) and a plurality of word lines WL. Each memory cell is, for example, associated with one bit line BL and one word line WL.

The input/output circuit 11 is an interface circuit that controls communication of input/output signals to and from the memory controller 2. The input/output signals include, for example, data DAT, status information, address information, commands, and the like. The input/output circuit 11 can input and output data DAT between the sense amplifier module 17 and the memory controller 2, respectively. The input/output circuit 11 can output the status information transferred from the register circuit 13 to the memory controller 2. The input/output circuit 11 can output each of the address information and the command transferred from the memory controller 2 to the register circuit 13.

The logic controller 12 controls each of the input/output circuit 11 and the sequencer 14 based on a control signal input from the memory controller 2. For example, the logic controller 12 controls the sequencer 14 to enable the memory device 1. The logic controller 12 notifies the input/output circuit 11 that the input/output signal received by the input/output circuit 11 is a command, address information, or the like. The logic controller 12 instructs the input/output circuit 11 to input or output an input/output signal.

The register circuit 13 temporarily stores status information, address information, and commands. The status information is updated under the control of the sequencer 14 and transferred to the input/output circuit 11. The address information includes a block address, a page address, a column address, and the like. The commands include instructions regarding various operations of the memory device 1.

The sequencer 14 controls the overall operation of the memory device 1. The sequencer 14 executes a read operation, a write operation, an erasing operation, and the like based on the command and address information stored in the register circuit 13.

The driver circuit 15 generates voltages used in a read operation, a write operation, an erasing operation, and the like. The driver circuit 15 then applies the generated voltage to the row decoder module 16, the sense amplifier module 17, and the like.

The row decoder module 16 is a circuit used for selecting a block BLK to be operated and for applying a voltage to a wiring such as a word line WL. The row decoder module 16 includes a plurality of row decoders RD0 to RDn. The row decoders RD0 to RDn are associated with blocks BLK0 to BLKn, respectively, and are used to select the block BLK. Each row decoder RD applies the voltage generated by the driver circuit 15 to various wirings provided in the memory cell array 10.

The sense amplifier module 17 is a circuit used for applying a voltage to each bit line BL and for reading data. The sense amplifier module 17 includes a plurality of sense amplifier units SAU0 to SAUm. The sense amplifier units SAU0 to SAUm are associated with a plurality of bit lines BL0 to BLm, respectively. Each sense amplifier unit SAU includes a sense amplifier capable of determining data based on the voltage of an associated bit line BL, a latch circuit for temporarily latching data, and the like.

The combination of the memory device 1 and the memory controller 2 may constitute one semiconductor device. Examples of such semiconductor devices include memory cards such as SDTM cards and solid state drives (SSDs).

### <1-2> Circuit Configuration of Memory Cell Array 10

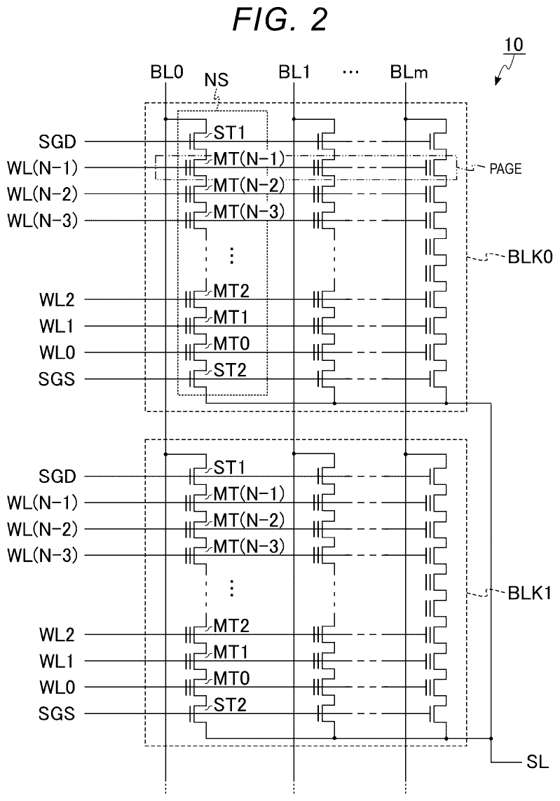

FIG. 2 is a circuit diagram showing a circuit configuration of the memory cell array 10 provided in the memory device 1. FIG. 2 shows two blocks BLK0 and BLK1 out of the plurality of blocks BLK provided in the memory cell array 10. As shown in FIG. 2, in the memory cell array 10, select gate lines SGD and SGS and word lines WL0 to WL(N-1) (N is an integer equal to or greater than 2) are provided for each block BLK. The bit lines BL0 to BLm and a source line SL are shared by, for example, a plurality of blocks BLK.

Each block BLK includes a plurality of NAND strings NS. A plurality of NAND strings NS are associated with the bit lines BL0 to BLm, respectively. In other words, each bit line BL is shared by NAND strings NS to which the same column address is assigned among a plurality of blocks BLK. Each NAND string NS is connected between an associated bit line BL and a source line SL. Each NAND string NS includes, for example, N memory cell transistors MT0 to MT(N-1) and select transistors ST1 and ST2. Each memory cell transistor MT is a memory cell having a control gate and a charge storage layer, and latches or stores data in a non-volatile manner. Each of the select transistors ST1 and ST2 is used to select a block BLK.

In each NAND string NS, the select transistor ST1, the memory cell transistors MT(N-1) to MT0, and the select transistor ST2 are connected in series in this order. Specifically, the drain terminal and the source terminal of the select transistor ST1 are connected to the associated bit line BL and the drain terminal of the memory cell transistor MT(N-1), respectively. The drain terminal and the source terminal of the select transistor ST2 are connected to the source terminal of the memory cell transistor MT0 and the source line SL, respectively. The memory cell transistors MT0 to MT(N-1) are connected in series between the select transistors ST1 and ST2.

Each select gate line SGD is connected to the gate terminal of each of the plurality of select transistors ST1 provided in the associated block BLK. The select gate line SGS is connected to the gate terminal of each of the plurality of select transistors ST2 provided in the associated block BLK. The word lines WL0 to WL(N-1) are respectively connected to the respective control gate terminals of the plurality of memory cell transistors MT0 to MT(N-1) provided in the associated block BLK. A “page” corresponds to a set of a plurality of memory cell transistors MT connected to a common word line WL within the same block BLK. A set of a plurality of memory cell transistors MT connected to a common word line WL in the same block BLK may have a storage capacity of two or more pages of data depending on the number of bits stored in the memory cell transistors MT.

The memory cell array 10 may have a different circuit configuration. For example, each block BLK may be provided with a plurality of select gate lines SGD that can be controlled independently. In this case, each block BLK is selectable in units of a plurality of units each corresponding to a plurality of select gate lines SGD.

In the following, the memory device 1 will be described using an example in which each NAND string NS has eight memory cell transistors MT0 to MT7 connected to word lines WL0 to WL7, respectively (that is, N=8).

### <1-3> Structure of Memory Device 1

Hereinafter, a structure of the memory device 1 will be described.

In the drawings referred to below, a three-dimensional Cartesian coordinate system is used. An X direction corresponds to an extension direction of the word lines WL. A Y direction corresponds to an extension direction of the bit lines BL. A Z direction corresponds to a direction perpendicular to the front surface of a semiconductor substrate which is used as a reference. “Up and down” are defined based on the direction along the Z direction. A positive or upward direction corresponds to a direction away from the semiconductor substrate which is used as the reference. An XY plane corresponds to a plane or cross section parallel to each of the X direction and the Y direction. A YZ cross section corresponds to a cross section parallel to each of the Y direction and the Z direction. An XZ cross section corresponds to a cross section parallel to each of the X direction and the Z direction.

### 1: Appearance of Memory Device 1

First, an appearance of the memory device 1 will be described. The memory device 1 is formed by bonding two semiconductor circuit substrates, each having a semiconductor circuit formed thereon, and then separating the bonded semiconductor circuit substrates into individual chips. That is, the memory device 1 includes a structure formed by bonding together semiconductor substrates W1 and W2. Each of the semiconductor substrates W1 and W2 is a silicon substrate. In the following, a case in which the semiconductor substrate W2 is removed in the manufacturing process of the memory device 1 will be described. Depending on the structure of the memory cell array 10, a part of the semiconductor substrate W2 may remain after bonding the semiconductor substrates W1 and W2.

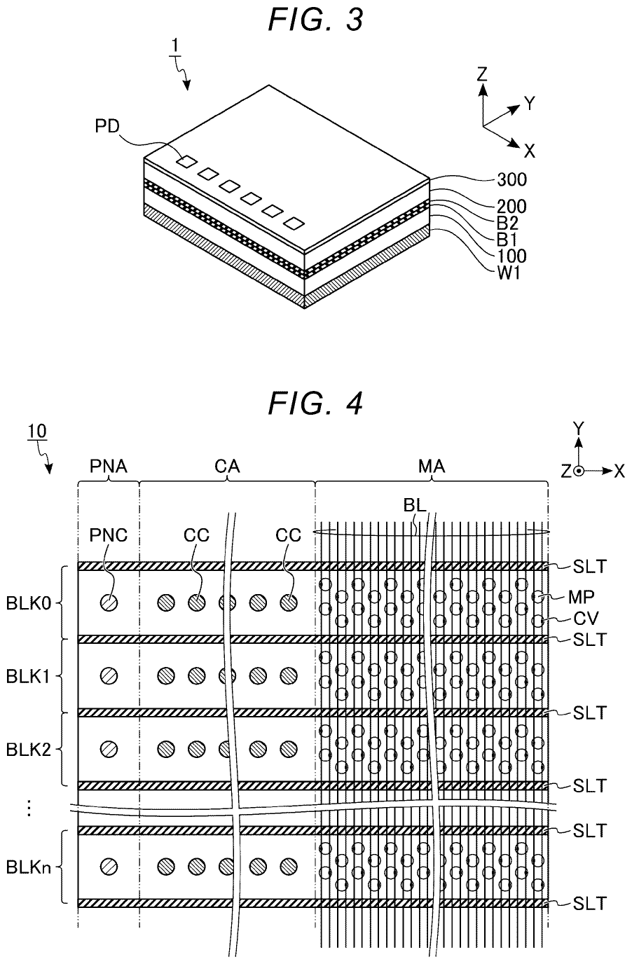

FIG. 3 is a perspective view showing the appearance of the memory device 1. As shown in FIG. 3, the memory device 1 has a structure in which, for example, a semiconductor substrate W1, a CMOS layer 100, a bonding layer B1, a bonding layer B2, a memory layer 200, and a wiring layer 300 are stacked in order from the bottom.

The CMOS layer 100 includes a CMOS circuit formed by utilizing the semiconductor substrate W1. The semiconductor substrate W1 has an impurity diffusion area and the like in accordance with the design of the CMOS circuit. The CMOS layer 100 includes, for example, control circuits such as an input/output circuit 11, a logic controller 12, a register circuit 13, a sequencer 14, a driver circuit 15, a row decoder module 16, and a sense amplifier module 17.

The bonding layer B1 is formed by utilizing the semiconductor substrate W1. The bonding layer B1 includes a plurality of bonding pads that are electrically connected to the CMOS circuit provided in the CMOS layer 100 to form a portion of the semiconductor circuit. The bonding layer B2 is formed by utilizing a semiconductor substrate W2 (not shown). The bonding layer B2 includes a plurality of bonding pads that are electrically connected to the memory cell array 10 provided in the memory layer 200 to form a portion of the semiconductor circuit. A plurality of bonding pads provided in the bonding layer B1 are respectively connected to a plurality of bonding pads provided in the bonding layer B2. The area between the bonding layers B1 and B2 corresponds to a boundary portion between a layer formed using the semiconductor substrate W1 and a layer formed using the semiconductor substrate W2 (not shown).

The memory layer 200 includes the memory cell array 10 formed by utilizing the semiconductor substrate W2. The wiring layer 300 is formed after the semiconductor substrates W1 and W2 are bonded together. The wiring layer 300 includes a wiring connected to the semiconductor circuits provided in the memory layer 200 and a plurality of pads PD. The plurality of pads PD are exposed on the front surface of the memory device 1. The plurality of pads PD are used to connect the memory device 1 to the memory controller 2 and the like.

### 2: Planar Layout of Memory Cell Array 10

FIG. 4 is a plan view showing a planar layout of the memory cell array 10 provided in the memory device 1. As shown in FIG. 4, the memory cell array 10 includes a plurality of slits SLT, a plurality of memory pillars MP, a plurality of contacts CC, and a plurality of PN contacts PNC. The memory cell array 10 also includes, for example, a memory area MA, a contact area CA, and a PN contact area PNA arranged in the X direction.

Each slit SLT is a plate-like member extending along the X direction. Each slit SLT has a portion extending along the X direction, and crosses the memory area MA, the contact area CA, and the PN contact area PNA along the X direction. The plurality of slits SLTs are arranged in the Y direction. Each slit SLT divides adjacent wirings (for example, word lines WL0 to WL7 and select gate lines SGD and SGS) via the slit SLT. In each slit SLT, a conductor having an insulating spacer provided on the side wall may be disposed to be insulated from these wirings, or an insulator may be embedded. In the memory cell array 10, each of the areas partitioned along the Y direction by the slits SLT corresponds to one block BLK.

The memory area MA is an area used for storing data. In the memory area MA, a plurality of memory pillars MP are disposed. Each memory pillar MP is, for example, a pillar shaped member that functions as one NAND string NS. A plurality of memory pillars MP are disposed in a lattice pattern for each block BLK. At least one bit line BL overlaps each memory pillar MP. The plurality of bit lines BL each have a portion extending in the Y direction, and are arranged in the X direction. In this example, two bit lines BL overlap one memory pillar MP. An electrical connection is established between the associated memory pillar MP and bit line BL via a contact CV.

The contact area CA is an area used for connection between the stacked wiring (for example, the word lines WL, the select gate lines SGD and SGS) provided in the memory cell array 10 and the row decoder module 16. In the contact area CA, a plurality of contacts CC are disposed for each block BLK. For each block BLK, each of the plurality of contacts CC is electrically connected to one associated wiring among the stacked wirings. In each block BLK, at least one contact CC is electrically connected to each of the select gate line SGS, the word lines WL0 to WL7, and the select gate line SGD. In the contact area CA, the plurality of contacts CC in each block BLK are not limited to being arranged in a line in the X direction as shown in FIG. 4, but may be disposed in a lattice pattern for each block BLK.

The PN contact area PNA is an area including a contact used for a conduction process for electrically connecting the stacked wiring provided in the memory cell array 10 and the plurality of contacts CC. In the PN contact area PNA, at least one PN contact PNC is disposed for each block BLK. The PN contact PNC is configured such that a voltage can be applied thereto by, for example, the row decoder module 16. The PN contact PNC and the stacked wiring are connected via a PN junction. The conduction process will be described in detail later.

### 3: Cross-Sectional Structure in Memory Area MA of Memory Cell Array 10

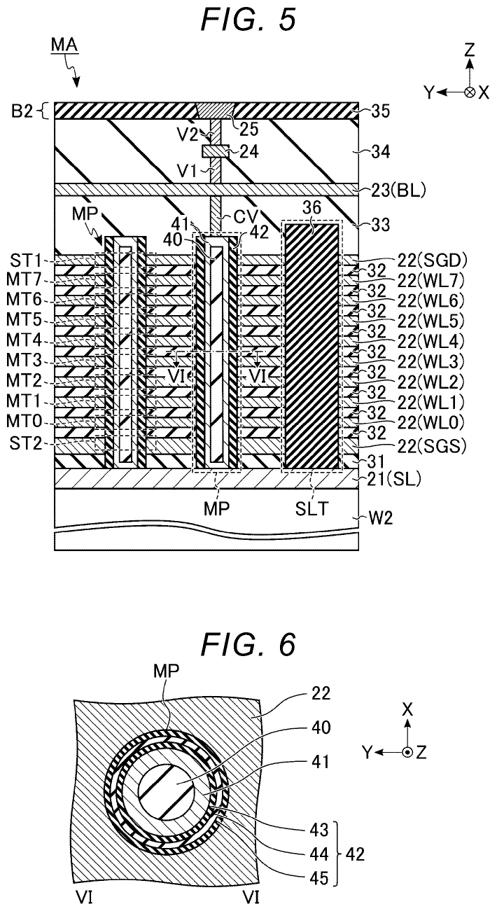

FIG. 5 is a cross-sectional view showing a cross-sectional structure in the memory area MA of the memory cell array 10 provided in the memory device 1. FIG. 5 shows an example of the structure of the memory cell array 10 formed on the semiconductor substrate W2 before being bonded to the semiconductor substrate W1, and indicates coordinate axes with the semiconductor substrate W2 as a reference. As shown in FIG. 5, the memory cell array 10 includes, for example, conductive layers 21 to 25, insulator layers 31 to 35, an insulating member 36, and contacts CV, V1, and V2 in the memory area MA.

The conductive layer 21 is provided on the semiconductor substrate W2. The insulator layer 31 is provided on the conductive layer 21. On the insulator layer 31, the conductive layer 22 and the insulator layer 32 are provided alternately. That is, a plurality of conductive layers 22 are arranged in the Z direction. The number of layers of the conductive layer 22 corresponds to, for example, the number of layers of the stacked wiring (i.e., select gate line SGS, word line WL, and select gate line SGD). On the uppermost conductive layer 22, the insulator layer 33, the conductive layer 23, the insulator layer 34, and the insulator layer 35 are provided in this order. Each of the conductive layers 21 and 22 is formed, for example, in a plate shape extending along the XY plane. The conductive layer 23 has, for example, a portion formed in a line shape extending in the Y direction. The conductive layer 21 is used as a source line SL. In this example, the ten conductive layers 22 arranged in the Z direction are used as, in order from the source line SL side, a select gate line SGS, word lines WL0 to WL7, and a select gate line SGD. The conductive layer 23 is used as a bit line BL.

The conductive layer 24 is provided above the conductive layer 23. The conductive layer 24 is a wiring that relays the connection between the bit line BL and the sense amplifier module 17. The conductive layer 23 and the conductive layer 24 are connected via the contact V1. The conductive layer 25 is provided above the conductive layer 24. The conductive layer 25 corresponds to the bonding pad. The conductive layer 25 includes, for example, copper. The conductive layer 24 and the conductive layer 25 are connected via the contact V2. The side surfaces of the conductive layer 24 and the contacts V1 and V2 are covered with the insulator layer 34. The insulator layer 34 may be configured with a plurality of insulating films. The side surfaces of the conductive layer 25 are covered with the insulator layer 35. The insulator layer 35 and the conductive layer 25 are provided in the bonding layer B2. The memory cell array 10 may include a plurality of conductive layers 24 and a plurality of conductive layers 25.

The slits SLT divide the insulator layer 31 and the conductive layers 22 and the insulator layers 32 that are alternately provided. In this example, the insulating member 36 is embedded in the slit SLT. The insulating member 36 has a portion formed in a plate shape extending along an XZ plane. In the slit SLT, a conductor having an insulating spacer provided on the side wall may be disposed to be insulated from stacked wirings.

Each memory pillar MP extends along the Z direction, and penetrates the insulator layer 31 and the conductive layers 22 and the insulator layers 32 that are provided alternately. Each memory pillar MP includes, for example, a core member 40, a semiconductor layer 41, and a stacked film 42. The core member 40 is an insulator extending along the Z direction. The semiconductor layer 41 covers the core member 40. The lower portion of the semiconductor layer 41 is in contact with, for example, the conductive layer 21. The stacked film 42 covers the side surfaces of the semiconductor layer 41. The associated semiconductor layer 41 (or the memory pillar MP) and the conductive layer 23 (or the bit line BL) are connected via the contact CV.

The portion where the conductive layer 22 used as the select gate line SGS intersects with the memory pillar MP functions as a select transistor ST2. The portion where the conductive layer 22 used as the word line WL intersects with the memory pillar MP functions as a memory cell transistor MT. The portion where the conductive layer 22 used as the select gate line SGD intersects with the memory pillar MP functions as a select transistor ST1. In each memory pillar MP, the semiconductor layer 41 is used as a channel (i.e., a current path) for the memory cell transistors MT0 to MT7 and the select transistors ST1 and ST2 provided in the NAND string NS.

### 4: Cross-Sectional Structure of Memory Pillar MP

FIG. 6 is a cross-sectional view taken along line VI-VI in FIG. 5, showing a cross-sectional structure of the memory pillar MP provided in the memory device 1. FIG. 6 shows a cross section including the memory pillar MP and the conductive layer 22 and parallel to the front surface of the semiconductor substrate W2. As shown in FIG. 6, the stacked film 42 includes, for example, a tunnel insulating film 43, an insulating film 44, and a block insulating film 45. The tunnel insulating film 43 surrounds the side surface of the semiconductor layer 41. The insulating film 44 surrounds the side surface of the tunnel insulating film 43. The block insulating film 45 surrounds the side surface of the insulating film 44. The conductive layer 22 surrounds the side surface of the block insulating film 45. Each of the tunnel insulating film 43 and the block insulating film 45 includes, for example, silicon oxide (SiO2). The insulating film 44 is used as a charge storage layer for the memory cell transistor MT. The insulating film 44 includes, for example, silicon nitride (SIN).

### 5: Cross-Sectional Structure in Contact Area CA and PN Contact Area PNA of Memory Cell Array 10

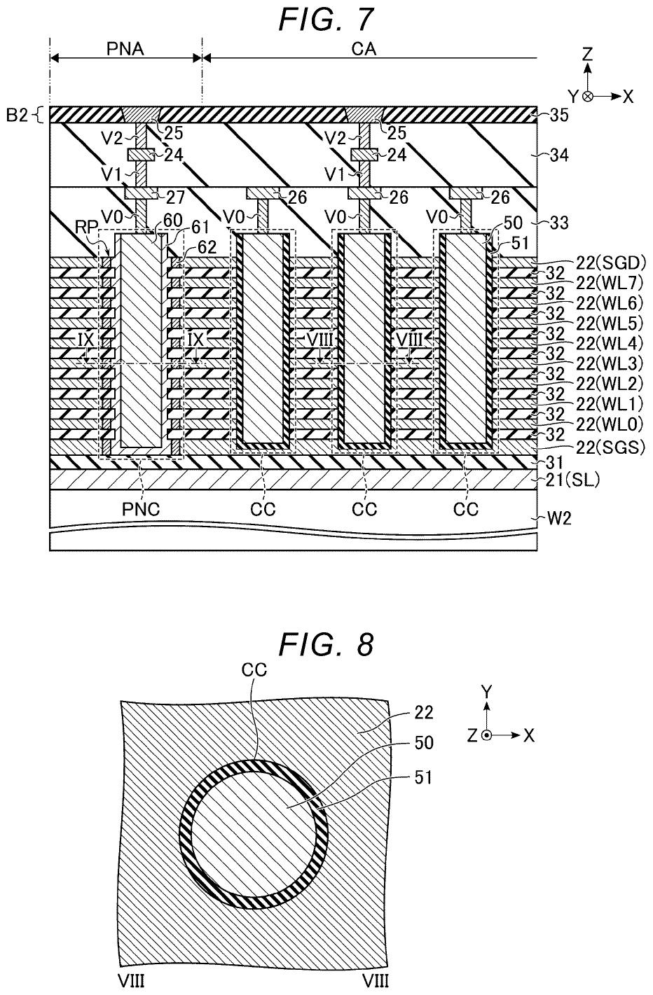

FIG. 7 is a cross-sectional view showing a cross-sectional structure in the contact area CA and the PN contact area PNA of the memory cell array 10 provided in the memory device 1. FIG. 7 shows an example of the structure of the memory cell array 10 formed on the semiconductor substrate W2 before being bonded to the semiconductor substrate W1, and indicates coordinate axes with the semiconductor substrate W2 as a reference. As shown in FIG. 7, the memory cell array 10 includes conductive layers 21 to 25, insulator layers 31 to 35, and contacts V0, V1, and V2 in the contact area CA and the PN contact area PNA. The conductive layers 21 and 22 and the insulator layers 31 to 35 are each provided continuously from the memory area MA to the contact area CA and the PN contact area PNA. Each of the contact area CA and the PN contact area PNA does not have a stacked wiring (i.e., conductive layer 22) processed into a stepped shape. Moreover, the memory cell array 10 further includes a plurality of conductive layers 26 and a plurality of contacts VO in the contact area CA, and further includes a conductive layer 27 and a contact V0 in the PN contact area PNA.

In the contact area CA, the length of each contact CC in the Z direction is substantially equal. Each contact CC penetrates a plurality of insulator layers 32 and two or more conductive layers 22, and is in contact with a plurality of conductive layers 22 including the uppermost conductive layer 22 and the lowermost conductive layer 22. In this example, the bottom surface of each contact CC is in contact with the lowermost conductive layer 22. Each contact CC may penetrate the lowermost conductive layer 22. In the contact area CA, the stacked wiring (i.e., the conductive layers 22) is not processed in a stepped shape, and therefore each contact CC is provided penetrating the plurality of conductive layers 22 having the same number as each other. Each contact CC includes a conductive member 50 and an insulating film 51. The conductive member 50 extends in the Z direction. The insulating film 51 covers the side surface and the bottom surface of the conductive member 50. The conductive member 50 has a portion that faces each of the plurality of conductive layers 22 via the insulating film 51.

The plurality of conductive layers 26 are wirings provided corresponding to the plurality of contacts CC. Each conductive layer 26 is disposed, for example, at the same height as the conductive layer 23. The bottom portion of each conductive layer 26 is connected to the conductive member 50 in the associated contact CC via the contact V0. The upper portion of each conductive layer 26 is connected to the conductive layer 25 via the contacts V1 and V2 and the conductive layer 24.

In the PN contact area PNA, the height of the upper surface (i.e., the end portion farther from the source line SL) of the PN contact PNC is aligned with the height of the upper surface (i.e., the end portion farther from the source line SL) of the contact CC. The PN contact PNC penetrates the plurality of insulator layers 32 and two or more conductive layers 22, and is in contact with the plurality of conductive layers 22 including the uppermost conductive layer 22 and the lowermost conductive layer 22. In this example, the bottom surface of the PN contact PNC is in contact with the lowermost conductive layer 22. The PN contact PNC may penetrate the lowermost conductive layer 22. The PN contact PNC has recess portions RP corresponding to the plurality of conductive layers 22, respectively. The diameter of the PN contact PNC is large at the recess portion RP. That is, the side surface of the PN contact PNC has a step. Furthermore, the PN contact PNC includes a conductive member 60, a P-type semiconductor layer 61, and an N-type semiconductor layer 62. The conductive member 60 extends in the Z direction. The P-type semiconductor layer 61 covers the side surface and the bottom surface of the conductive member 50. The N-type semiconductor layer 62 covers the side surfaces of the P-type semiconductor layer 61 at each recess portion RP of the PN contact PNC. The conductive member 60 has a portion that faces each of the plurality of conductive layers 22 via the P-type semiconductor layer 61 and the N-type semiconductor layer 62.

The conductive layer 27 is a wiring provided corresponding to the PN contact PNC. The conductive layer 27 is disposed, for example, at the same height as the conductive layer 23. The bottom portion of the conductive layer 27 is connected to the conductive member 60 in the associated PN contact PNC via the contact V0. The upper portion of the conductive layer 27 is connected to the conductive layer 25 via the contacts V1 and V2 and the conductive layer 24.

### 6: Cross-Sectional Structure of Contact CC Before Conduction

FIG. 8 is a cross-sectional view taken along line VIII-VIII in FIG. 7, showing a cross-sectional structure of the contact CC before conduction, which is provided in the memory device 1. FIG. 8 shows a cross section that includes the contact CC and the conductive layer 22 and is parallel to the front surface of the semiconductor substrate W2 before the contact CC and the conductive layer 22 are electrically connected to each other. As shown in FIG. 8, in the contact CC, the insulating film 51 surrounds the side surface of the conductive member 50. The conductive layer 22 surrounds the side surface of the insulating film 51. In this manner, before the contacts CC and the conductive layers 22 are electrically connected to each other, each conductive layer 22 and the conductive member 50 in the contact CC are separated and insulated from each other via the insulating film 51. The conductive member 50 includes, for example, tungsten (W). The insulating film 51 includes, for example, silicon oxide (SiO2).

### 7: Cross-Sectional Structure of PN Contact PNC

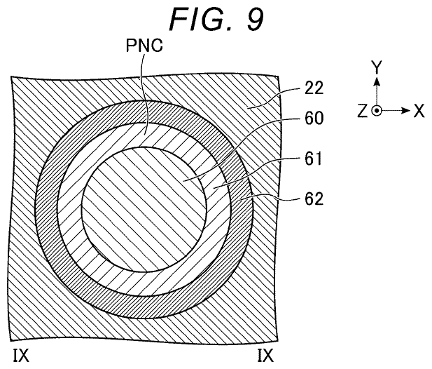

FIG. 9 is a cross-sectional view taken along line IX-IX in FIG. 7, showing a cross-sectional structure of the PN contact PNC provided in the memory device 1. FIG. 9 shows a cross section including the PN contact PNC and the conductive layer 22 and parallel to the front surface of the semiconductor substrate W2. As shown in FIG. 9, in the PN contact PNC, the P-type semiconductor layer 61 surrounds the side surface of the conductive member 60. The N-type semiconductor layer 62 surrounds the side surface of the P-type semiconductor layer 61. The conductive layer 22 surrounds the side surface of the N-type semiconductor layer 62. In this manner, the conductive member 60 in the PN contact PNC and the conductive layer 22 are connected via the P-type semiconductor layer 61 and the N-type semiconductor layer 62. That is, the conductive member 60 in the PN contact PNC and the conductive layer 22 are connected via a PN junction configured with the P-type semiconductor layer 61 and the N-type semiconductor layer 62. In this example, the direction from the conductive member 60 of the PN contact PNC toward the conductive layer 22 corresponds to the forward direction of the PN junction. The conductive member 60 includes, for example, tungsten (W). The P-type semiconductor layer 61 includes, for example, silicon doped with boron (B). The N-type semiconductor layer 62 includes, for example, silicon doped with phosphorus (P).

### 8: Cross-Sectional Structure of Memory Device 1

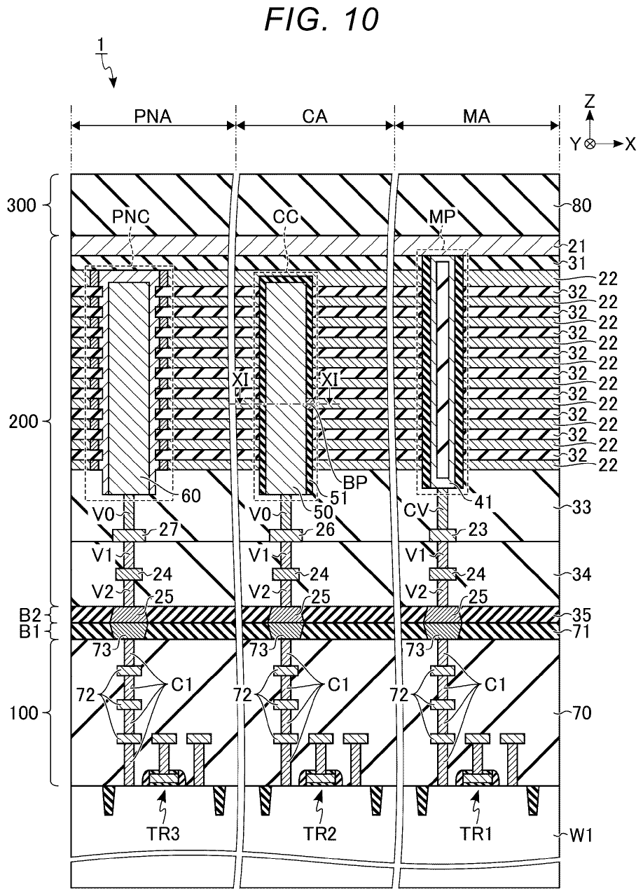

FIG. 10 is a cross-sectional view showing a cross-sectional structure of the memory device 1. FIG. 10 indicates coordinate axes with the semiconductor substrate WI as a reference after the contact CC and the conductive layer 22 are electrically connected to each other. As shown in FIG. 10, the memory device 1 has a configuration in which the structure of the memory cell array 10 described with reference to FIGS. 5 and 7 is disposed in an inverted manner up and down, except that in the memory layer 200, the contact CC and the conductive layer 22 are electrically connected to each other. In this example, the semiconductor substrate W2 is removed after the bonding process of the semiconductor substrates W1 and W2. The memory cell array 10 includes an insulator layer 70, a plurality of conductive layers 72, and a plurality of contacts C1 in the CMOS layer 100, an insulator layer 71 and a plurality of conductive layers 73 in the bonding layer B1, and an insulator layer 80 in the wiring layer 300. Transistors TR1 to TR3 are provided on the semiconductor substrate W1. The transistor TR1 corresponds to an element provided in the sense amplifier module 17. Each of the transistors TR2 and TR3 corresponds to an element provided in the row decoder module 16.

The insulator layer 70 is provided on the semiconductor substrate W1. The insulator layer 70 may be configured with a plurality of insulating films. Within the insulator layer 70, at least one contact C1 and at least one conductive layer 72 are connected in series on each of the transistors TR1, TR2, and TR3.

The insulator layer 71 is provided on the insulator layer 70. The conductive layer 73 corresponds to a bonding pad formed by utilizing the semiconductor substrate W1, and is in contact with the upper portion of the associated contact C1. For example, the conductive layer 73 in the memory area MA is connected to the transistor TR1 via at least one contact C1 and at least one conductive layer 72. For example, the conductive layer 73 in the contact area CA is connected to the transistor TR2 via at least one contact C1 and at least one conductive layer 72. For example, the conductive layer 73 in the PN contact area PNA is connected to the transistor TR3 via at least one contact C1 and at least one conductive layer 72. Each conductive layer 73 is in contact with a corresponding conductive layer 25 (i.e., a corresponding bonding pad).

The insulator layer 80 is provided on the conductive layer 21. The insulator layer 80 includes, for example, the plurality of pads PD described with reference to FIG. 3, and a wiring for connecting the plurality of pads PD to the input/output circuit 11 provided on the semiconductor substrate W1 (not shown).

After a conduction process described below is executed, a conductive member 50 of each contact CC is electrically connected to any one of the plurality of conductive layers 22 with which it is in contact via an insulating breakdown portion BP. The insulating breakdown portion BP is formed by causing insulation breakdown at a local portion of the insulating film 51 provided in a ring shape in an XY cross section through a conduction process. The position in the Z direction of the conductive layer 22 to which each contact CC is electrically connected through a conduction process may differ for each block BLK. That is, in the memory device 1, the memory cell array 10 includes a plurality of blocks BLK, each of which includes a plurality of conductive layers 22, a plurality of memory pillars MP, and a plurality of contacts CC, and a connection relationship between the plurality of conductive layers 22 and the plurality of contacts CC may differ for each block BLK.

### 9: Cross-Sectional Structure of Contact CC After Conduction

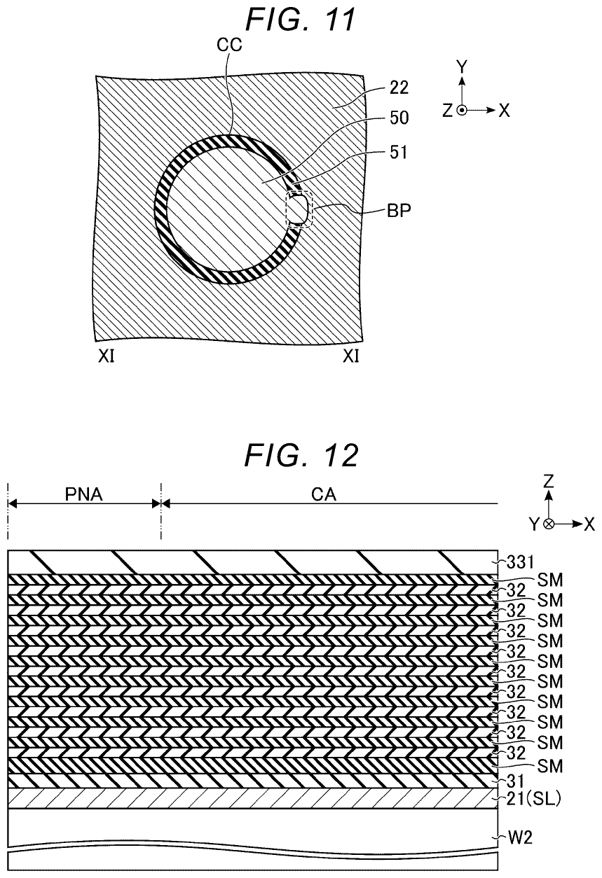

FIG. 11 is a cross-sectional view taken along line XI-XI in FIG. 10, showing an example of a cross-sectional structure of the contact CC after conduction, which is provided in the memory device 1. FIG. 11 shows a cross section that includes the electrically connected contact CC and conductive layer 22 and is parallel to the front surface of the semiconductor substrate W1 after the contact CC and the conductive layer 22 are electrically connected to each other. As shown in FIG. 11, after the conduction process, the conductive member 50 in the contact CC and one of the conductive layers 22 are electrically connected to each other via the insulating breakdown portion BP. In this example, a state is shown in which a part of the insulating film 51 is broken by insulation breakdown, and a part of the conductive member 50 moves toward the conductive layer 22 side. Therefore, in the XY cross section, the conductive layer 22 and the conductive member 50 in the contact CC are locally connected at one location. In other words, in a cross section parallel to the front surface of the semiconductor substrate W1, the conductive member 50 has its outer edge surrounded by the corresponding conductive layer 22, and is electrically connected to the corresponding conductive layer 22 at one location (i.e., the locally insulating breakdown portion BP) of the outer edge. The insulating film 51 covers the side surface of the conductive member 50 except for the connection portion (i.e., the insulating breakdown portion BP) between the conductive member 50 and the corresponding conductive layer 22. The insulating breakdown portion BP includes, for example, tungsten (W) similarly to the conductive member 50.

### <2> Manufacturing Method

Next, a method for manufacturing the memory device 1 will be described. In this specification, the term “stacked wiring portion” refers to a structure (i.e., a stacked body) used to form a stacked wiring including a plurality of word lines WL arranged in the Z direction.

### <2-1> Method for Forming Memory Cell Array 10

Each of FIGS. 12, 13, 14, 15, 16, 17, 18, and 19 is a cross-sectional view showing a cross-sectional structure during a manufacturing process of the memory cell array 10 provided in the memory device 1. Each of FIGS. 12 to 19 shows a process of forming three contacts CC in the contact area CA and one PN contact PNC in the PN contact area PNA shown in FIG. 7 using a semiconductor substrate W2.

First, as shown in FIG. 12, a plurality of sacrificial members SM corresponding to the stacked wiring portion are formed. Specifically, first, the conductive layer 21 and the insulator layer 31 are provided in this order on the semiconductor substrate W2. Then, on the insulator layer 31, the sacrificial members SM and insulator layers 32 are alternately stacked. The number of layers of the sacrificial members SM corresponds to the number of layers of the conductive layers 22. Then, an insulator layer 331 is provided on the uppermost sacrificial member SM. The insulator layer 331 corresponds to a portion of the insulator layer 33 shown in FIG. 7.

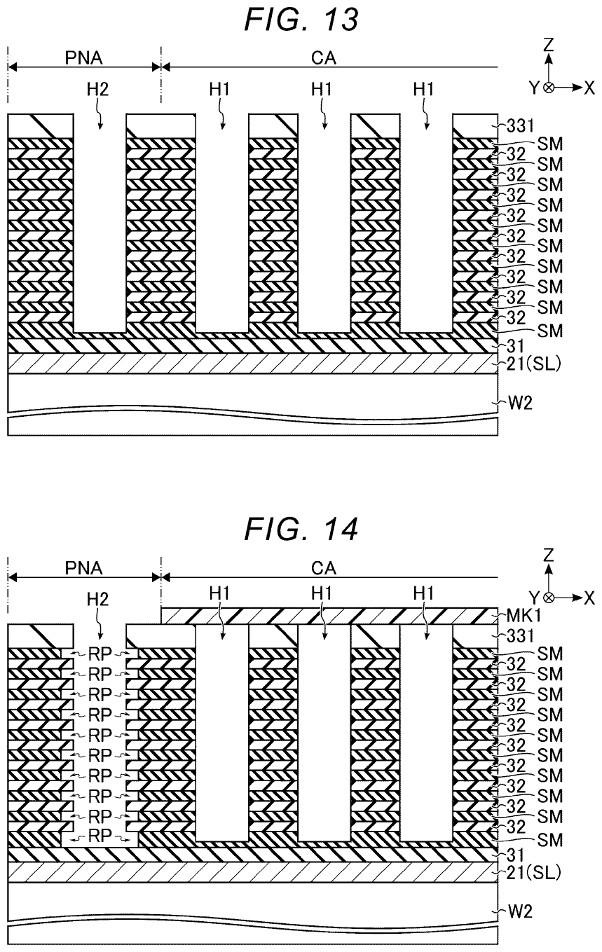

Next, as shown in FIG. 13, a plurality of holes H1 and H2 are formed. Each hole H1 is provided corresponding to one contact CC. The hole H2 is provided corresponding to one PN contact PNC. Each of the holes H1 and H2 penetrates the insulator layer 331, the plurality of insulator layers 32, and the plurality of sacrificial members SM. In this example, the bottom portion of each of the holes H1 and H2 reaches the lowermost sacrificial member SM. At the bottom portion of each of the holes H1 and H2, the lowermost sacrificial member SM is exposed. Each of the holes Hl and H2 may penetrate the lowermost sacrificial member SM. In this step, for example, reactive ion etching (RIE) is used.

Next, as shown in FIG. 14, a plurality of recess portions RP are formed in the hole H2. Specifically, first, a mask MK1 that covers the contact area CA is formed. The mask MK1 is, for example, a photoresist. Then, a part of the sacrificial member SM exposed in the hole H2 is selectively removed by an isotropic etching process. Accordingly, a plurality of recess portions RP are formed in the hole H2 corresponding to the plurality of sacrificial members SM, respectively. The isotropic etching process used in this step is, for example, wet etching.

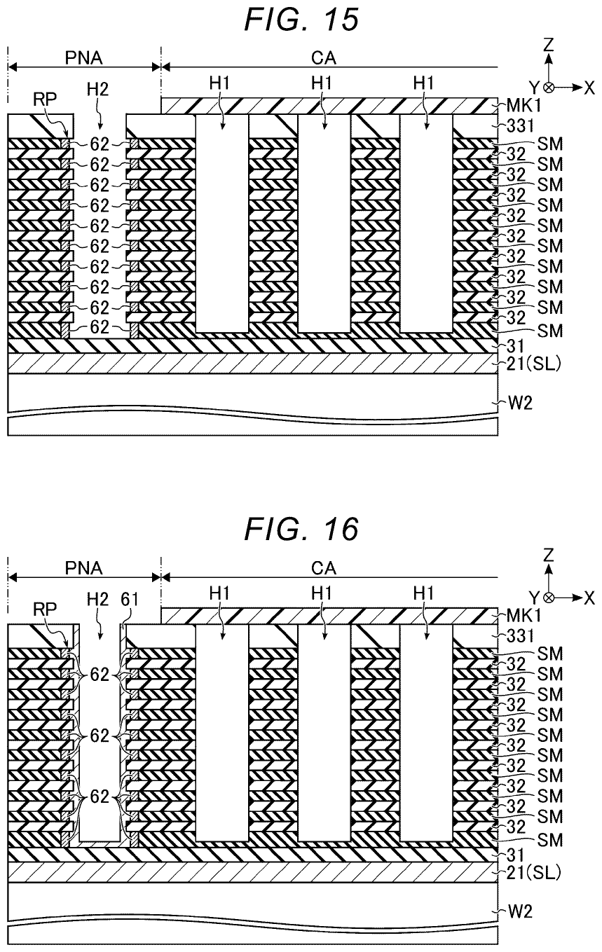

Next, as shown in FIG. 15, an N-type semiconductor layer 62 is formed in the hole H2. Specifically, first, the N-type semiconductor layer 62 is formed in the hole H2 such that each of the recess portions RP is embedded. The N-type semiconductor layer 62 is formed by, for example, chemical vapor deposition (CVD). Then, the N-type semiconductor layer 62 in the hole H2 is separated into each recess portion RP, and is removed to remain in each recess portion RP.

Next, as shown in FIG. 16, a P-type semiconductor layer 61 is formed in the hole H2. The P-type semiconductor layer 61 is formed by, for example, CVD. The P-type semiconductor layer 61 formed in the hole H2 is in contact with the N-type semiconductor layer 62 in each recess portion RP. Accordingly, a PN junction is formed in each recess portion RP of the hole H2. After the P-type semiconductor layer 61 is formed, the mask MK1 is removed.

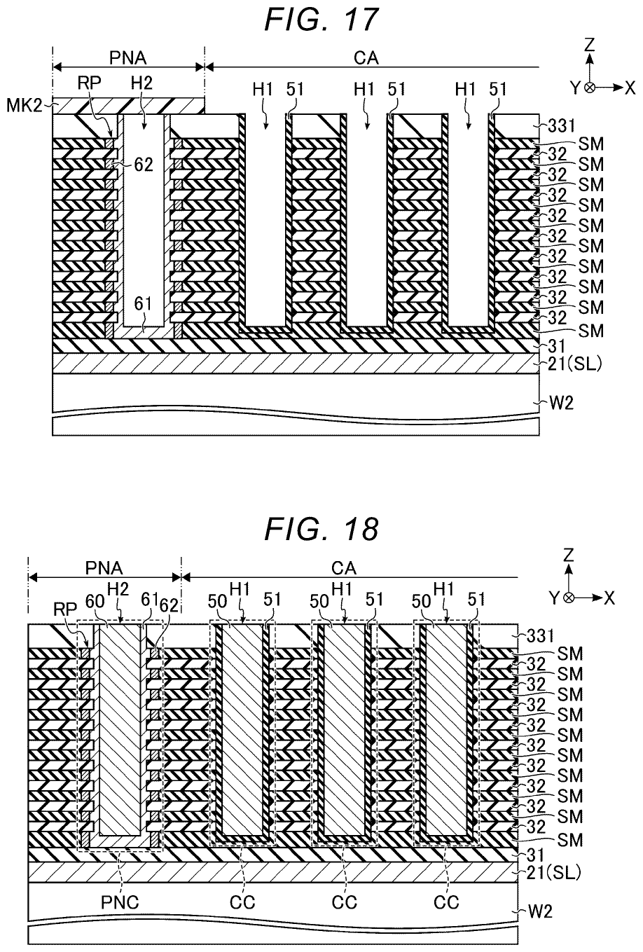

Next, as shown in FIG. 17, an insulating film 51 is formed in each hole H1. Specifically, first, a mask MK2 that covers the PN contact area PNA is formed. The mask MK2 is, for example, a photoresist. The insulating film 51 is provided on the side surface and the bottom surface of each hole H1 to be in contact with all of the stacked sacrificial members SM. After the insulating film 51 is formed, the mask MK2 is removed.

Next, as shown in FIG. 18, a conductor is embedded in each of the holes H1 and H2. The conductor embedded in the hole H1 corresponds to the conductive member 50, and the conductor embedded in the hole H2 corresponds to the conductive member 60. Accordingly, a structure corresponding to the contact CC is formed in each hole H1, and a structure corresponding to the PN contact PNC is formed in each hole H2.

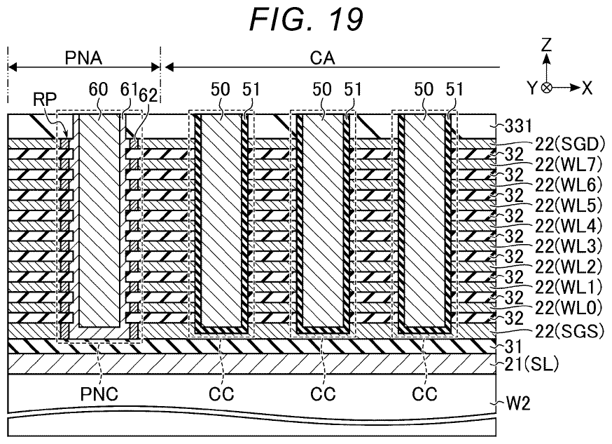

Next, a replacement process is executed. Specifically, first, in an area not shown, slits SLT are formed to divide the plurality of sacrificial members SM into blocks BLK. Then, the plurality of sacrificial members SM are selectively removed via the slits SLT by wet etching process using hot phosphoric acid or the like. Then, a conductor is embedded via the slit SLT into the space from which the sacrificial member SM has been removed. In this step, the conductor is formed by, for example, CVD. Then, the conductor formed in the slit SLT is removed by an etch-back process or the like, and the conductors formed in the adjacent spaces are separated into a plurality of layers. Accordingly, as shown in FIG. 19, a plurality of conductive layers 22 are formed which function as the select gate line SGS, the word lines WL0 to WL7, and the select gate line SGD.

The combination of functions of the stacked wiring formed by the replacement process is not limited to the plurality of conductive layers 22 (i.e., select gate lines SGS and SGD and word lines WL) described above. Depending on the structure of the memory cell array 10, the source line SL (i.e., the conductive layer 21) may be formed by a replacement process, similarly to the conductive layer 22. In this case, the lowermost sacrificial member SM corresponds to the conductive layer 21.

### <2-2> Conduction Method Between Stacked Wiring and Contact CC

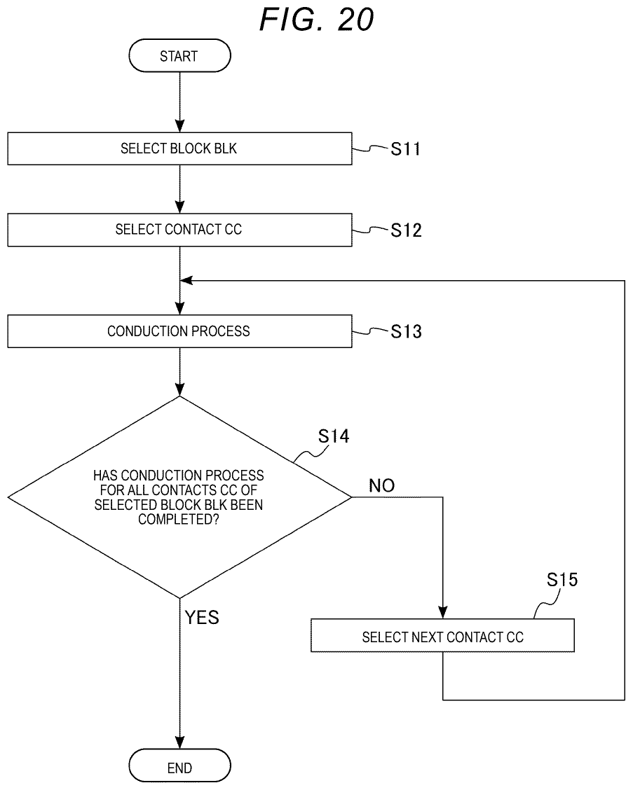

FIG. 20 is a flowchart showing a conduction method between the stacked wiring and the contact CC provided in the memory device 1. Hereinafter, with reference to FIG. 20, a conduction method of the contact CC with respect to the stacked wiring will be described with attention to one block BLK.

First, a block BLK in which conduction between the contact CC and the conductive layer 22 is not completed is selected (step S11). Next, a contact CC is selected from the selected block BLK (step S12). Next, a conduction process is executed for the selected contact CC (step S13). By the conduction process, the selected contact CC is electrically connected to any of the conductive layers 22 provided in the stacked wiring.

Next, it is confirmed whether the conduction process for all the contacts CC of the selected block BLK has been completed (step S14). When the conduction process has not been completed for all the contacts CC of the selected block BLK (step S14: NO), the next contact CC is selected (step S15), and the process proceeds to step S13. That is, a conduction process is executed in which the next contact CC is selected. When the conduction process is executed, the next contact CC is electrically connected to any of the conductive layers 22 that have not been electrically connected to the contact CC by the conduction process up to this point in the stacked wiring. When the conduction process for all the contacts CC of the selected block BLK has been completed (step S14: YES), the series of processes in FIG. 20 is completed. Then, the series of processes shown in FIG. 20 is executed for each of all blocks BLK.

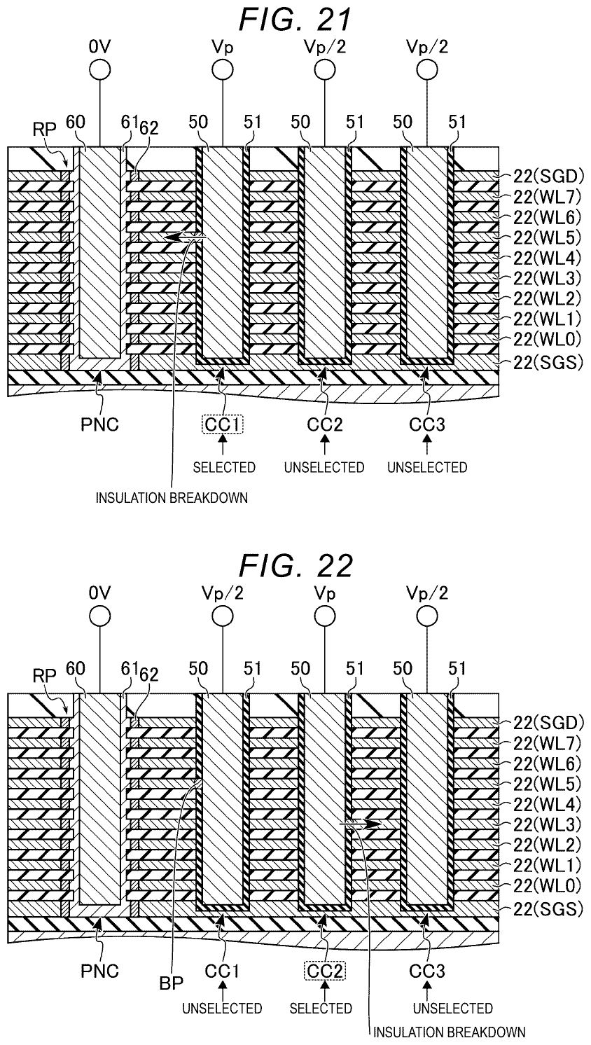

A case in which the conduction process is executed sequentially on three contacts CC will be described below with reference to FIGS. 21, 22, and 23. FIGS. 21, 22, and 23 are schematic views showing a conduction process between a stacked wiring and contacts CC provided in the memory device 1. Each of FIGS. 21, 22, and 23 shows a stacked wiring (that is, a plurality of conductive layers 22) corresponding to the contact area CA and the PN contact area PNA shown in FIG. 19, three contacts CC, and a PN contact PNC, and voltages applied to each of the three contacts CC and the PN contact PNC. In the following, the three contacts CC shown in the drawing will be referred to as contacts CC1, CC2, and CC3, respectively, in order from the left side of the page.

FIG. 21 corresponds to a state before all the contacts CC in the selected block BLK are electrically connected to the stacked wiring. As shown in FIG. 21, in this example, the contact CCI is selected as the target for the conduction process, and the other contacts CC are not selected. In this case, the row decoder module 16 applies, for example, a voltage Vp to the selected contact CC1, a voltage Vp/2 to the unselected contacts CC2 and CC3, and a voltage of 0 V to the PN contact PNC. Vp is a high voltage capable of causing insulation breakdown of the insulating film 51 based on the difference between the voltage applied to each conductive layer 22 via the PN contact PNC.

A forward bias voltage is applied to the PN junction provided in each recess portion RP by a voltage applied to the PN contact PNC. Therefore, the voltage of each conductive layer 22 becomes 0 V. When Vp is applied to the selected contact CCI, a high electric field is generated between the conductive member 50 in the contact CC1 and each conductive layer 22 via the insulating film 51. Then, an insulation breakdown occurs at the location of the insulating film 51 of the contact CC1 that has the lowest breakdown voltage (in this example, one location at the intersection portion of the conductive layer 22 corresponding to the word line WL5 and the contact CC1).

Accordingly, the contact CC1 and the conductive layer 22 corresponding to the word line WL5 are electrically connected to each other. After the insulation breakdown occurs, the voltage of the word line WL5 rises, but since Vp/2 is applied to the unselected contacts CC2 and CC3, the electric field applied to the insulating film 51 of each of the unselected contacts CC2 and CC3 remains small. Therefore, secondary breakdown of the insulating film 51 is reduced in each of the unselected contacts CC2 and CC3. Furthermore, as the voltage of the word line WL5 rises, a reverse bias voltage is applied to the PN junction at the intersection of the word line WL5 and the PN contact PNC. This reduces the influence of the voltage of the word line WL5 on the PN contact PNC.

FIG. 22 shows a state in which the conduction process is performed on the contact CC2 after the conduction process on the contact CC1 shown in FIG. 21. As shown in FIG. 22, in this example, the contact CC2 is selected as the target for the conduction process, and the other contacts CC1 and CC3 are not selected. In this case, the row decoder module 16 applies, for example, a voltage Vp to the selected contact CC2, a voltage Vp/2 to the unselected contacts CC1 and CC3, and a voltage of 0 V to the PN contact PNC.

The voltage applied to the PN contact PNC sets the voltage of each conductive layer 22 to 0 V. When Vp/2 is applied to the contact CC1, which is already conductive, the voltage of the word line WL5 rises to Vp/2. At this time, at the intersection of the word line WL5 and the PN contact PNC, a reverse bias voltage is applied to the PN junction of the recess portion RP, so that the influence on the PN contact PNC is reduced. When Vp is applied to the selected contact CC2, a high electric field is generated between the conductive member 50 in the contact CC2 and each conductive layer 22 except for the word line WL5 via the insulating film 51. Then, an insulation breakdown occurs at the location of the insulating film 51 of the contact CC2 that has the lowest breakdown voltage excluding the intersection with the word line WL5 to which Vp/2 is applied (in this example, one location at the intersection portion of the conductive layer 22 corresponding to the word line WL3 and the contact CC2).

Accordingly, the contact CC2 and the conductive layer 22 corresponding to the word line WL3 are electrically connected to each other. After the insulation breakdown occurs, the voltage of the word line WL3 rises, but since Vp/2 is applied to the unselected contacts CC1 and CC3, the electric field applied to the insulating film 51 of each of the unselected contacts CC1 and CC3 remains small. As a result, secondary breakdown of the insulating film 51 is reduced in each of the unselected contacts CC1 and CC3. Furthermore, as the voltage of the word line WL3 rises, a reverse bias voltage is applied to the PN junction at the intersection of the word line WL3 and the PN contact PNC. This reduces the influence of the voltage of the word line WL3 on the PN contact PNC.

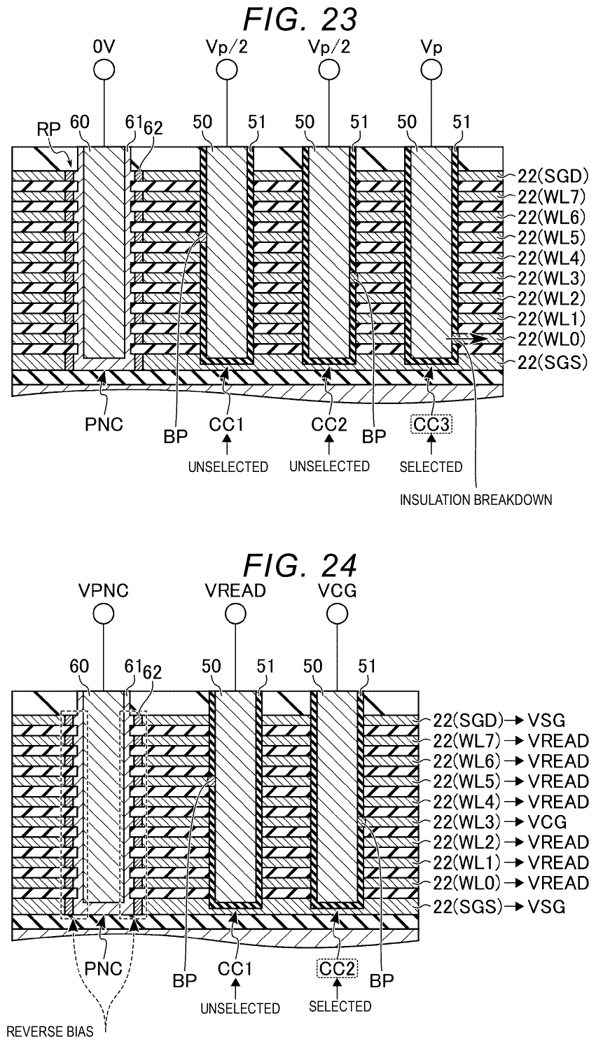

FIG. 23 shows a state in which the conduction process is performed on the contact CC3 after the conduction process on the contact CC2 shown in FIG. 22. As shown in FIG. 23, in this example, the contact CC3 is selected as the target for the conduction process, and the other contacts CC1 and CC2 are not selected. In this case, the row decoder module 16 applies, for example, a voltage Vp to the selected contact CC3, a voltage Vp/2 to the unselected contacts CC1 and CC2, and a voltage of 0 V to the PN contact PNC.

The voltage applied to the PN contact PNC sets the voltage of each conductive layer 22 to 0 V. When Vp/2 is applied to the contacts CC1 and CC2, which are already conductive, the voltage of the word lines WL3 and WL5 rises to Vp/2. At this time, at the intersection of each of the word lines WL3 and WL5 and the PN contact PNC, a reverse bias voltage is applied to the PN junction of the recess portion RP, so that the influence on the PN contact PNC is reduced. When Vp is applied to the selected contact CC3, a high electric field is generated between the conductive member 50 in the contact CC3 and each conductive layer 22 except for the word lines WL3 and WL5 via the insulating film 51. Then, an insulation breakdown occurs at the location of the insulating film 51 of the contact CC3 that has the lowest breakdown voltage excluding the intersection with the word lines WL3 and WL5 to which Vp/2 is applied (in this example, one location at the intersection portion of the conductive layer 22 corresponding to the word line WL0 and the contact CC3).

Accordingly, the contact CC3 and the conductive layer 22 corresponding to the word line WL0 are electrically connected to each other. After the insulation breakdown occurs, the voltage of the word line WL0 rises, but since Vp/2 is applied to the unselected contacts CC1 and CC2, the electric field applied to the insulating film 51 of each of the contacts CC1 and CC2 remains small. As a result, secondary breakdown of the insulating film 51 is reduced in each of the unselected contacts CC1 and CC2. Furthermore, as the voltage of the word line WL0 rises, a reverse bias voltage is applied to the PN junction at the intersection of the word line WL0 and the PN contact PNC. This reduces the influence of the voltage of the word line WL0 on the PN contact PNC.

As described above, the conduction process is executed by selecting the contacts CC one by one in sequence. The conduction process is executed, for example, during testing of the memory device 1 before shipment. Without being limited thereto, the conduction process may be executed using the semiconductor substrate W2 prior to the bonding process of the semiconductor substrates W1 and W2, as long as it is possible to apply the voltage as described above. In addition, in the conduction process, the voltage applied to the unselected contacts CC is not limited to Vp/2, and may be another voltage as long as it is possible to reduce insulation breakdown in the insulating film 51 of the unselected contacts CC. In addition, in the conduction process, the voltage applied to the PN contact PNC is not limited to 0 V. As the voltage applied to the unselected contacts CC, at least a voltage higher than the voltage applied to the PN contact PNC and lower than Vp is used.

### <3> Operation

Next, an operation of the memory device 1 will be described. A read operation will be described below as an example of the operation of the memory device 1.

FIG. 24 is a schematic view showing voltages applied to the stacked wiring, the contact CC, and the PN contact PNC in a read operation of the memory device 1. FIG. 24 shows the voltage applied to each of the stacked wiring (that is, the plurality of conductive layers 22), the two contacts CC1 and CC2, and the PN contact PNC.

As shown in FIG. 24, in this example, a memory cell transistor MT3 (not shown) connected to the word line WL3 is selected as a read target. In this case, in a read operation, the row decoder module 16 applies a voltage VSG to each of the select gate lines SGD and SGS, applies a read voltage VCG to the selected word line WL3 (that is, the contact CC2 connected to the selected word line WL3), applies a read pass voltage VREAD to the unselected word lines WL (for example, the contact CC1 connected to the unselected word line WL5), and applies a voltage VPNC to the PN contact PNC.

VSG is a voltage capable of turning on the select transistors ST1 and ST2. VREAD is a high voltage capable of turning on the memory cell transistor MT regardless of the data stored in the memory cell transistor MT. VCG is a read voltage used to determine the threshold voltage of the memory cell transistor MT. VREAD is higher than both VSG and VCG. VPNC is a voltage that causes the voltage applied to each PN junction formed in the PN contact PNC to be a reverse bias, regardless of the voltage applied to the stacked wiring. Specifically, VPNC is a voltage equal to or lower than the voltage applied to each of the plurality of conductive layers 22, for example, the ground voltage VSS (0 V).

Then, in the read operation, the voltage applied to each PN junction of the PN contact PNC is a reverse bias. Therefore, in a read operation, the influence of the voltage applied to the PN contact PNC on each conductive layer 22 can be reduced. When the above-mentioned voltages are applied, each of the select transistors ST1 and ST2 is turned on. The memory cell transistors MT connected to any of the unselected word lines WL0 to WL2 and WL4 to WL7 are turned on regardless of the data to be stored. The memory cell transistor MT3 connected to the selected word line WL3 is turned on or off in accordance with the data to be stored. As a result, the voltage of the bit line BL varies according to a threshold voltage of the memory cell transistor MT3 connected to the selected word line WL3. Then, the sense amplifier module 17 can determine data stored in the memory cell transistor MT3 connected to the selected word line WL3 based on the voltage of the bit line BL.

In addition, the voltage applied to the PN contact PNC in the write operation is set to a voltage such that the voltage applied to each PN junction formed in the PN contact PNC is a reverse bias, similarly to the read operation. Accordingly, the memory device 1 can execute a write operation without being affected by the voltage applied to the PN contact PNC.

### <4> Effects

With the memory device 1 described above, the manufacturing cost of the memory device 1 can be reduced. One or more effects achieved by the memory device 1 will be described in detail below.

A conventional memory device having memory cells stacked three-dimensionally has a memory pillar that penetrates a stacked wiring (or a stacked body) in which conductive layers (or conductive films) and insulator layers (or insulating films) are stacked alternately. In such a memory device, the contacts for the stacked wiring are connected to, for example, a stepped portion that is processed into a stepped shape at an end portion of the stacked wiring. However, when a stepped portion is formed, the area of the stepped portion increases as the number of layers in the stacked wiring increases. That is, this can be a factor in increasing the chip area. Furthermore, an increase in the number of layers in the stacked wiring increases the degree of difficulty of contact processing to different depths, which can be a factor in increasing manufacturing costs.

Therefore, the memory device 1 uses contacts CC that penetrate the stacked wiring and are electrically connected only to specific conductive layers 22. Specifically, the memory device 1 has a plurality of contacts CC formed at the same height in a contact area CA that is not processed into a stepped shape. Since the plurality of holes H1 for forming the contacts CC have the same depth, it is easier to process the holes H1 than to process holes having different depths. Then, the contact CC and the specific conductive layer 22 are electrically connected to each other by causing insulation breakdown of a part of the insulating film 51 of the contact CC through a conduction process.

In this manner, the memory device 1 uses an anti-fuse type contact structure for electrical connection between the contacts CC and the conductive layer 22. As a result, in the memory device 1, the step processing is omitted, so that the area of the contact area CA can be reduced. In addition, the degree of difficulty in contact processing for forming the contacts CC can be reduced. Therefore, the memory device 1 can reduce the chip area and the process development costs, and can reduce the manufacturing costs of the memory device 1.

### <5> Modification Examples ETC.

The memory device 1 described above can be modified in various ways.

### First Modification Example

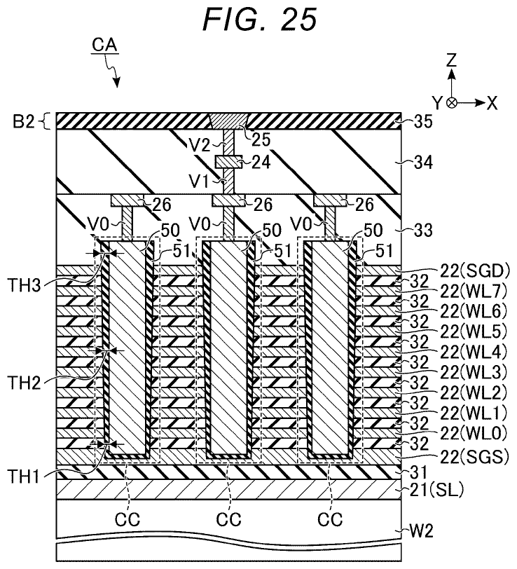

FIG. 25 is a cross-sectional view showing a cross-sectional structure in a contact area CA of a memory cell array 10 according to a first modification example. FIG. 25 shows an example of the structure of the memory cell array 10 formed on the semiconductor substrate W2 before being bonded to the semiconductor substrate W1, and indicates coordinate axes with the semiconductor substrate W2 as a reference. As shown in FIG. 25, an insulating film 51 provided in a contact CC in the first modification example becomes thinner toward the bottom side (i.e., the semiconductor substrate W2 side). In other words, the film thickness of the insulating film 51 increases from the bottom side to the top side of the contact CC. Specifically, a film thickness TH1 of the bottom side of the contact CC is thinner than a film thickness TH2 of the middle portion of the contact CC. The film thickness TH2 of the middle portion of the contact CC is thinner than a film thickness TH3 of the top side of the contact CC. The breakdown voltage of the insulating film 51 increases as the film thickness of the insulating film 51 increases. Therefore, in the first modification example, in the conduction process described above, insulation breakdown of the insulating film 51 will occur in order from the bottom. As a result, in the first modification example, the combination of the electrically connected contacts CC and the conductive layers 22 can be controlled to be approximately constant.

### Second Modification Example

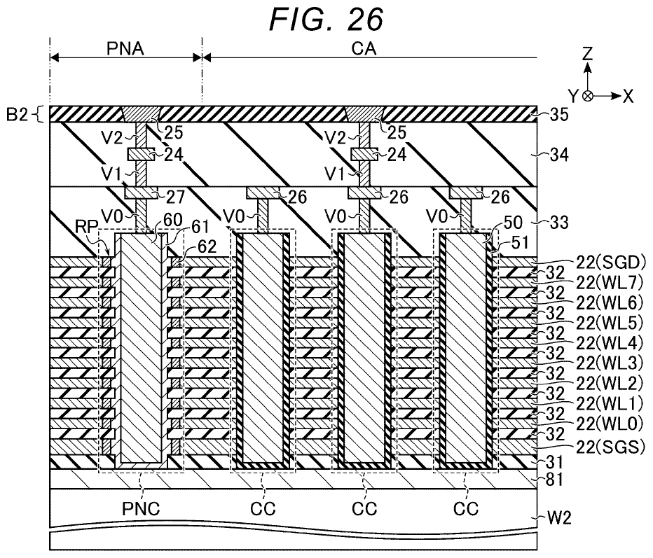

FIG. 26 is a cross-sectional view showing a cross-sectional structure in a contact area CA and a PN contact area PNA of a memory cell array 10 according to a second modification example. FIG. 26 shows an example of the structure of the memory cell array 10 formed on the semiconductor substrate W2 before being bonded to the semiconductor substrate W1, and indicates coordinate axes with the semiconductor substrate W2 as a reference. As shown in FIG. 26, in the second modification example, in the contact area CA and the PN contact area PNA, a stopper layer 81 is provided instead of the conductive layer 21 used as the source line SL. In this example, the stopper layer 81 is, for example, a silicon layer, and the conductive members 50 of each of the plurality of contacts CC are separated and insulated from the source line SL (the conductive layer 21) (not shown). The bottom portion of each contact CC and the bottom portion of the PN contact PNC penetrate the lowermost conductive layer 22 and reach the stopper layer 81. In this case, all of the conductive layers 22 are in contact with the side walls of each contact CC. As in the second modification example, the stopper layer 81 may be provided to control the position of the bottom portion of each of the contacts CC and the PN contact PNC. The position of the stopper layer 81 suffices to be provided further away from the bottom side of the contact CC than the lowermost conductive layer 22, and may be different from the height of the source line SL (i.e., conductive layer 21). When the source line SL (i.e., conductive layer 21) is formed by the same replacement process as the conductive layer 22, the stopper layer 81 may be provided further away from the bottom side of the contact CC than the conductive layer 21.

### Third Modification Example

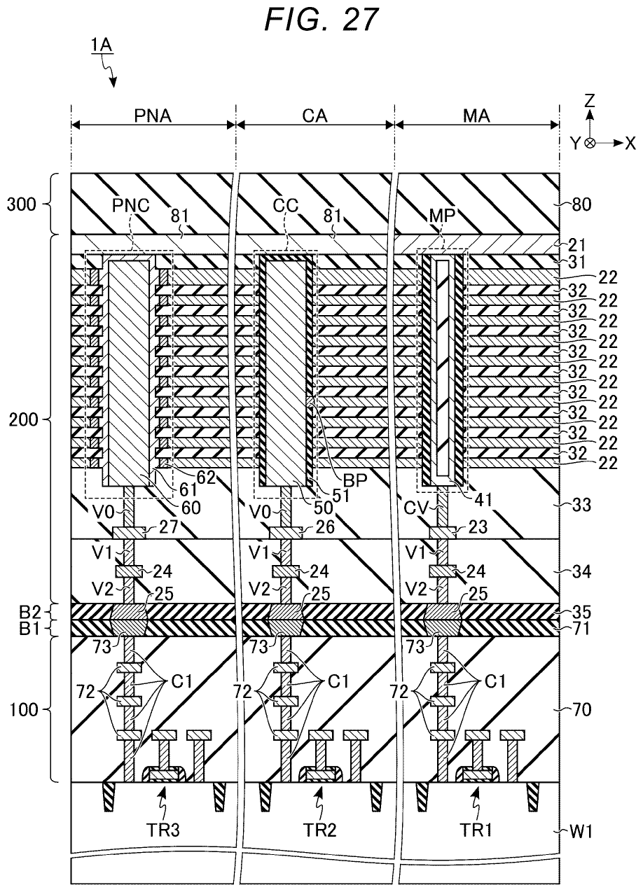

FIG. 27 is a cross-sectional view showing a cross-sectional structure of a memory device 1A according to a third modification example. FIG. 27 shows the same area as FIG. 10, and indicates coordinate axes with the semiconductor substrate W1 as a reference. The third modification example corresponds to a case where, in the above-described memory device 1, steps of forming holes corresponding to the memory pillar MP, the contact CC, and the PN contact PNC are executed all at once. In this example, similarly to the second modification example, the stopper layer 81 is provided in each of the contact area CA and the PN contact area PNA. When the steps of forming holes corresponding to the memory pillar MP, the contact CC, and the PN contact PNC are executed all at once, the heights of the lower end of the memory pillar MP (i.e., the end portion farther from the source line SL), the lower end of the contact CC (i.e., the end portion farther from the source line SL), and the lower end of the PN contact PNC (i.e., the end portion farther from the source line SL) are all aligned. When the steps of forming holes corresponding to the memory pillar MP, the contacts CC, and the PN contacts PNC are executed all at once as in the third modification example, the number of manufacturing steps can be reduced. Therefore, the memory device 1A according to the third modification example can reduce the manufacturing cost of the memory device 1A more than in the embodiment. In the third modification example, the case where the processing of the contacts CC and the PN contact PNC and the processing of the memory pillar MP are integrated has been illustrated, but the present disclosure is not limited thereto. Processing of the contacts CC and the PN contact PNC may be integrated with processing of the slits SLT and the like. Even in such a case, the manufacturing cost of the memory device 1A can be reduced.

### Fourth Modification Example

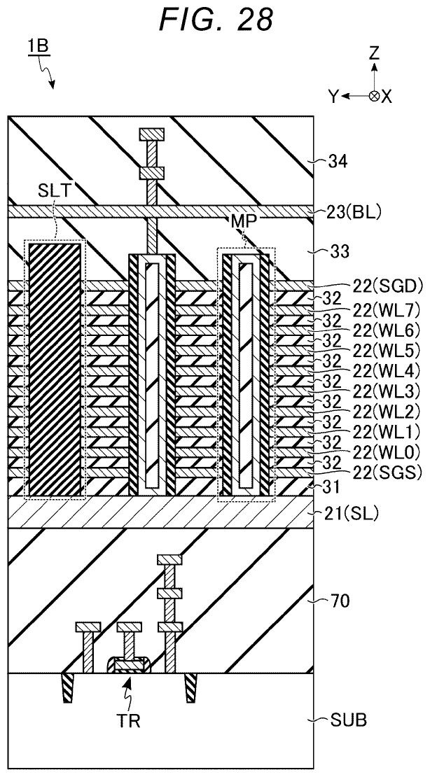

FIG. 28 is a cross-sectional view showing a cross-sectional structure of a memory device 1B according to a fourth modification example. The fourth modification example corresponds to the case where the memory device 1B is formed using one semiconductor substrate SUB and a CMOS circuit is disposed below a stacked wiring that constitutes a memory cell array 10, as shown in FIG. 28. In this case, in the memory device 1B, the source line SL (i.e., the conductive layer 21) is located between the semiconductor substrate SUB and the stacked wiring (i.e., the plurality of conductive layers 22). Even in such a case, the memory device 1B may have a configuration in which contacts CC and PN contacts PNC are formed as in the embodiment, and the contacts CC and the stacked wiring are electrically connected by executing a conduction process. As a result, the memory device 1B according to the fourth modification example can reduce the manufacturing cost of the memory device 1B.

### Fifth Modification Example

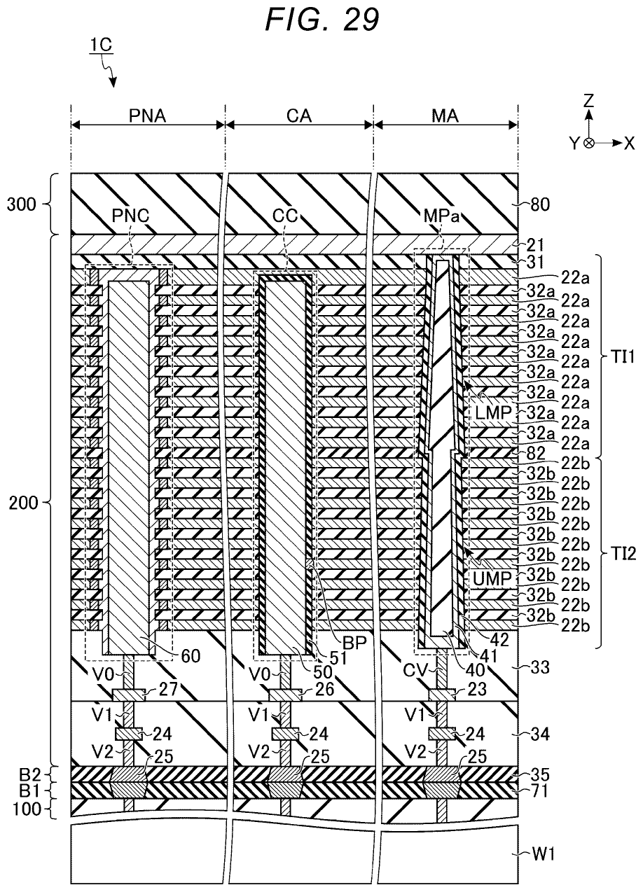

FIG. 29 is a cross-sectional view showing a cross-sectional structure of a memory device 1C according to a fifth modification example. FIG. 29 shows an example of the structure of the memory cell array 10 after the semiconductor substrates W1 and W2 are bonded together, and indicates coordinate axes with the semiconductor substrate W1 as a reference. In this example, after the semiconductor substrates W1 and W2 are bonded together, the semiconductor substrate W2 is removed, and the wiring layer 300 is formed. As shown in FIG. 29, the memory device 1C includes, for example, conductive layers 21, 22a, 22b, 23, and 24 to 27, insulator layers 31, 32a, 32b, 33 to 35, and 82, a memory pillar MPa, contacts CC, CV, and V0 to V2, and a PN contact PNC.

The memory cell array 10 in the fifth modification example is different from the memory cell array 10 in the embodiment in the structure between the insulator layer 31 and the insulator layer 33. Specifically, under the insulator layer 31, insulator layers 32a and conductive layers 22a are alternately provided. An insulator layer 82 is provided below the lowermost conductive layer 22a. Under the insulator layer 82, conductive layers 22b and insulator layers 32b are provided alternately. An insulator layer 33 is provided on the lowermost conductive layer 22b.

Each of the conductive layers 22a and 22b is formed, for example, in a plate shape extending along the XY plane. For example, the nine stacked conductive layers 22a are used as a select gate line SGS and eight word lines WL, in order from the conductive layer 21 side. For example, the nine stacked conductive layers 22b are used as eight word lines WL and a select gate lines SGD, in order from the conductive layer 21 side. Each of the conductive layers 22a and 22b includes, for example, tungsten (W). In the following, a division unit of the step of forming holes for forming the memory pillars MPa will be referred to as a tier TI. In this example, the memory device 1C includes tiers TI1 and TI2. The tier TI1 includes nine conductive layers 22a. The tier TI2 includes nine conductive layers 22b.

The memory pillar MPa has a structure in which a plurality of pillars, each of which extends along the Z direction, are connected together. In this example, the memory pillar MPa includes two pillars connected in the Z direction. In the following, these two pillars will be referred to as a lower pillar LMP and an upper pillar UMP based on a positional relationship when the memory hole is formed. The lower pillar LMP is associated with the tier TI1. The lower pillar LMP is provided penetrating each of the insulator layers 31, 32a, and 82 and the plurality of conductive layers 22a. The upper pillar UMP is provided below the lower pillar LMP and is associated with the tier TI2. The upper pillar UMP is provided penetrating each of the plurality of insulator layers 32b and the plurality of conductive layers 22b. The connecting portion of the lower pillar LMP and the upper pillar UMP is provided in a layer at the same height as the insulator layer 82 is provided.

The lower pillar LMP and the upper pillar UMP share the core member 40, the semiconductor layer 41, and the stacked film 42. That is, the core member 40, the semiconductor layer 41, and the stacked film 42 provided in the memory pillar MPa are each provided continuously between the lower pillar LMP and the upper pillar UMP. In this example, each of the lower pillar LMP and the upper pillar UMP has a taper shape. In this case, the XY cross-sectional area of the lower end of the lower pillar LMP is larger than the XY cross-sectional area of the upper end of the upper pillar UMP. The intersection portions between the lower pillar LMP and each of the nine conductive layers 22a function as, in order from the conductive layer 21 side, a select transistor ST2 and eight memory cell transistors MT. The intersection portions between the upper pillar UMP and each of the nine conductive layers 22b function as, in order from the conductive layer 21 side, eight memory cell transistors MT and a select transistor ST1.

In the fifth modification example, the contact CC and the PN contact PNC are in contact with all the conductive layers 22a and 22b. Specifically, in this example, the side surfaces of the contact CC and the PN contact PNC are in contact with the conductive layers 22a and 22b, respectively. The height (i.e., the length in the Z direction) of each contact CC is substantially the same. In the fifth modification example, the plurality of contacts CC associated with the block BLK are electrically connected to different conductive layers 22a or 22b via the insulating breakdown portions BP. Each of the contact CC and the PN contact PNC may penetrate the uppermost conductive layer 22a. The memory device 1C according to the fifth modification example has a configuration in which the contacts CC and the stacked wiring are electrically connected to each other.

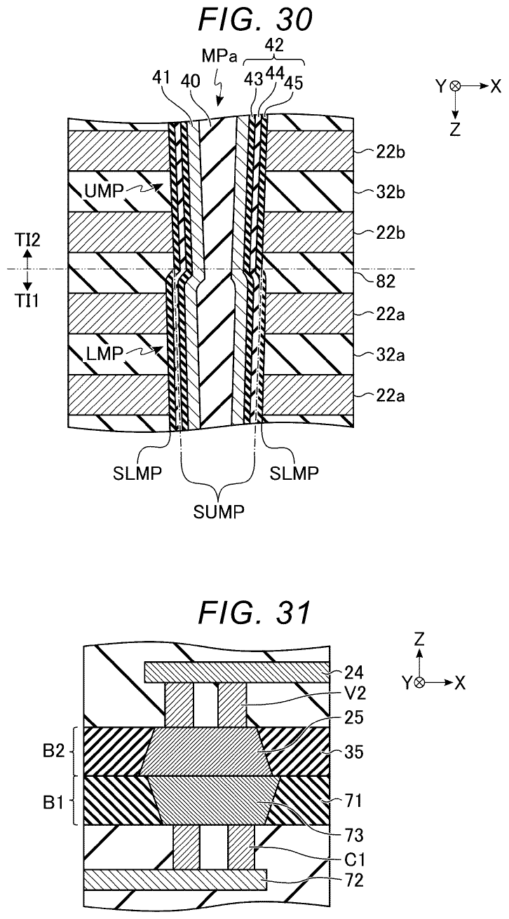

FIG. 30 is a cross-sectional view showing a detailed cross-sectional structure of the memory pillar MPa at the boundary portion between two tiers TI1 and TI2 provided in the memory device 1C according to the fifth modification example. In FIG. 30, the boundary portion between the tiers TI1 and TI2 is shown in an inverted manner up and down compared to FIG. 29. As shown in FIG. 30, for example, in the YZ cross section, the upper end of the lower pillar LMP may have a rounded shape instead of an angular shape. In this case, it cannot be said that the XY cross-sectional area of the upper end of the lower pillar LMP is clearly larger than the XY cross-sectional area of the lower end of the upper pillar UMP. However, the shape of the side surface of the memory pillar MPa is discontinuous at the boundary portion between the lower pillar LMP and the upper pillar UMP. Specifically, for example, in the YZ cross section, a side surface SLMP of the lower pillar LMP is deviated from the extension line of a side surface SUMP of the upper pillar UMP, which is indicated by the dashed line in FIG. 30. The deviation of the two side surfaces SLMP and SUMP can occur for any cross section including the Z direction, such as an XZ cross section. In this specification, the boundary portion between memory pillars MP in two tiers TI adjacent in the Z direction can be specified based on the discontinuous portion in the shape of the side surface of the memory pillar MP. The memory pillar MPa may have a structure in which three or more pillars, each of which extends along the Z direction, are connected together. Even in such a case, the memory pillar MPa may have a structure as shown in FIG. 30 at the boundary portion between adjacent tiers TI.

### Other Examples

FIG. 31 is a cross-sectional view showing a detailed cross-sectional structure of the vicinity of two bonding pads disposed opposite to each other in the memory device 1. FIG. 31 shows a conductive layer 73 (i.e., bonding pad) formed by utilizing a semiconductor substrate W1 (not shown), a conductive layer 25 (i.e., bonding pad) formed by utilizing a semiconductor substrate W2 (not shown), and some of the contacts C1 and V2 and conductive layers 72 and 24 connected thereto. As shown in FIG. 31, two bonding pads disposed opposite to each other may have different taper shapes based on the etching direction in which they are formed. Specifically, the conductive layer 73 formed by utilizing the semiconductor substrate W1 has, for example, an inverted taper shape. The conductive layer 25 formed by utilizing the semiconductor substrate W2 has, for example, a taper shape. Therefore, the cross section along the Z direction at the portion where the conductive layer 73 and the conductive layer 25 are bonded may have a non-rectangular shape rather than a straight side wall. Furthermore, a set including two bonding pads disposed opposite to each other may be bonded with a deviation depending on the alignment during the bonding process. Therefore, a step may be formed between the upper surface of the conductive layer 73 and the lower surface of the conductive layer 25. The set including the two bonding pads disposed opposite to each other may have a boundary or may be integrated. The bonding pads and the contacts C1 and V2 connected to the bonding pads may be formed integrally. A plurality of corresponding contacts C1 and V2 may be connected to a bonding pad. For example, the conductive layer 73 may be connected to the conductive layer 72 via a plurality of contacts C1. Similarly, the conductive layer 25 may be connected to the conductive layer 24 via a plurality of contacts V2.

The circuit configuration, the planar layout, and the cross-sectional structure of the memory device 1 may each be changed as appropriate. The PN contact area PNA may be removed after the conduction process described in the embodiment is executed. The memory pillar MP may have a structure in which a pillar corresponding to the select gate line SGD and a pillar corresponding to the word line WL are connected. The memory pillar MP and the bit line BL may be connected to each other by a plurality of contacts connected in the Z direction. A conductive layer may be inserted between the connecting portions of the plurality of contacts. The number of wiring layers and contacts provided in the memory device 1 can be changed as appropriate depending on the circuit design. The memory pillar MP may have a taper shape, an inverted taper shape, or a bowing shape. The slit SLT may have a taper shape, an inverted taper shape, or a bowing shape. The top, middle, and bottom of the columnar elements described in the embodiment are based on their positional relationship during hole processing. That is, the portion corresponding to the bottom portion of the hole corresponds to the bottom, the portion corresponding to the central portion of the hole corresponds to the middle, and the portion corresponding to the opening of the hole corresponds to the top. The XY cross-sectional structure of the memory pillar MP and a support column for a replacement process (not shown) may be circular or elliptical. In this specification, the “XY cross-sectional area” corresponds to the cross-sectional area in a cross section parallel to the semiconductor substrate W1 or W2. Each wiring in the stacked wiring may include a metal oxide film around a conductor such as tungsten. In a stacked wiring, the conductive layers that are alternately stacked with the insulator layers may be considered as a configuration including such a metal oxide film.

The manufacturing step described above is merely an example. For example, other processes may be inserted between the respective manufacturing steps, and the order of the manufacturing steps may be changed as long as no problems arise. In this specification, “connected” refers to being electrically connected, and does not exclude, for example, having another element therebetween. The term “electrically connected” may be used via an insulator as long as it is possible for the two to operate in the same manner as when they are electrically connected. The term “taper shape” refers to a shape that becomes thinner as it moves away from a reference member. The term “inverted taper shape” refers to a shape that becomes thicker as it moves away from a reference member. The term “columnar” indicates that the structure is provided in a hole formed in the manufacturing step of the memory device 1. The “diameter” refers to the inner diameter of a hole or the outer diameter of a pillar in a cross section (i.e., XY cross section) parallel to the front surface of the substrate. The “semiconductor substrate” may also be referred to simply as a “substrate”. The “semiconductor layer” may also be referred to as a “conductive layer”. The “area” may be considered to be a configuration included by the substrate. For example, when the semiconductor substrate W1 is defined as including a memory area MA and a contact area CA, the memory area MA and the contact area CA are respectively associated with different areas above the semiconductor substrate W1. The “height” corresponds to, for example, an interval in the Z direction between the configuration to be measured and the semiconductor substrate W1. As the reference for the “height”, a configuration other than the semiconductor substrate W1 may be used. The “top (or plan) view” corresponds to, for example, viewing the front surface of the semiconductor substrate W1 from a direction perpendicular to the semiconductor substrate W1.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A memory device comprising:
a substrate;
a plurality of conductive layers arranged in a first direction above the substrate;
a plurality of pillars, each of which extends along the first direction and intersects with the conductive layers, wherein a memory cell is formed at an intersection of one of the pillars and one of the conductive layers; and
a plurality of first contacts each extending along the first direction and electrically connected to a corresponding one of the conductive layers, wherein
each of the first contacts includes:
a first conductive member extending along the first direction,
a first connection portion in contact with a side surface of the first conductive member and the corresponding conductive layer to electrically connect the first conductive member to the corresponding conductive layer, and
a first insulating film surrounding the side surface of the first conductive member except at a location of the first connection portion.

2. The memory device according to claim 1, wherein the first insulating film of each of the first contacts is surrounded by the corresponding conductive layer.

3. The memory device according to claim 1, wherein a thickness of a first part of the first insulating film is different from a thickness of a second part of the first insulating film that is located farther from the substrate than the first part.

4. The memory device according to claim 1, further comprising:
a silicon layer that contacts one end in the first direction of each of the first contacts and is electrically insulated from the first conductive member thereof.

5. The memory device according to claim 1, further comprising:
a plurality of memory blocks including a first memory block and a second memory block adjacent to the first memory block, wherein
the first memory block includes the plurality of conductive layers, the plurality of pillars, and the plurality of first contacts,
the second memory block includes:
another plurality of conductive layers arranged in the first direction above the substrate and corresponding to the plurality of conductive layers of the first memory block,
another plurality of pillars, each of which extends along the first direction and intersects with said another plurality of conductive layers, wherein a memory cell is formed at an intersection of one of said another plurality of pillars and one of said another plurality of conductive layers, and
another plurality of first contacts corresponding to the plurality of first contacts of the first memory block and each extending along the first direction and electrically connected to a corresponding one of said another plurality of conductive layers, wherein
each of said another plurality of first contacts includes:
a second conductive member extending along the first direction,
a second connection portion in contact with a side surface of the second conductive member and the corresponding conductive layer to electrically connect the second conductive member to the corresponding conductive layer, and
a second insulating film surrounding the side surface of the second conductive member except at a location of the second connection portion, and
one of the first contacts of the first memory block is electrically connected to a first conductive layer of the first memory block, and one of the first contacts of the second memory block that corresponds to said one of the first contacts of the first memory block is electrically connected to a second conductive layer of the second memory block, the first conductive layer not corresponding to the second conductive layer.

6. The memory device according to claim 1, wherein lengths of the first contacts in the first direction are substantially the same.

7. The memory device according to claim 1, wherein the first conductive member of each of the first contacts is insulated from the other conductive layers by the first insulating film.

8. The memory device according to claim 1, further comprising:
a second contact that extends along the first direction and includes a conductive member connected to the conductive layers via different PN junctions.

9. The memory device according to claim 8, wherein the second contact further includes:
a plurality of N-type semiconductor layers corresponding to the conductive layers, and
a P-type semiconductor layer provided on a side surface of the conductive member of the second contact and forming a PN junction with each of the N-type semiconductor layers.

10. The memory device according to claim 8, further comprising:
a sequencer configured to execute a read operation, wherein the sequencer applies, to the second contact, a voltage that is equal to or less than a voltage applied to each of the conductive layers when reading data stored in the memory cell.

11. A memory device comprising:
a substrate;
a plurality of conductive layers arranged in a first direction above the substrate;
a plurality of pillars, each of which extends along the first direction and intersects with the conductive layers, wherein a memory cell is formed at an intersection of one of the pillars and one of the conductive layers; and
a plurality of first contacts, each of which extends along the first direction, penetrates the conductive layers, and is electrically connected to one of the conductive layers.

12. The memory device according to claim 11, wherein each of the first contacts includes:
a first conductive member extending along the first direction,
a first connection portion in contact with a side surface of the first conductive member and one of the conductive layers to electrically connect the first conductive member to said one of the conductive layers, and
a first insulating film surrounding the side surface of the first conductive member except at a location of the first connection portion.

13. The memory device according to claim 12, wherein a thickness of a first part of the first insulating film is different from a thickness of a second part of the first insulating film that is located farther from the substrate than the first part.

14. The memory device according to claim 12, further comprising:
a silicon layer that contacts one end in the first direction of each of the first contacts and is electrically insulated from the first conductive member thereof.

15. The memory device according to claim 11, further comprising:
a plurality of memory blocks including a first memory block and a second memory block adjacent to the first memory block, wherein
the first memory block includes the plurality of conductive layers, the plurality of pillars, and the plurality of first contacts, and
the second memory block includes:
another plurality of conductive layers arranged in the first direction above the substrate and corresponding to the plurality of conductive layers of the first memory block,
another plurality of pillars, each of which extends along the first direction and intersects with said another plurality of conductive layers, wherein a memory cell is formed at an intersection of one of said another plurality of pillars and one of said another plurality of conductive layers, and
another plurality of first contacts corresponding to the plurality of first contacts of the first memory block and each extending along the first direction, penetrating said another plurality of conductive layers, and electrically connected to one of said another plurality of conductive layers, and
one of the first contacts of the first memory block is electrically connected to a first conductive layer of the first memory block, and one of the first contacts of the second memory block that corresponds to said one of the first contacts of the first memory block is electrically connected to a second conductive layer of the second memory block, the first conductive layer not corresponding to the second conductive layer.

16. The memory device according to claim 11, wherein lengths of the first contacts in the first direction are substantially the same.

17. The memory device according to claim 11, wherein each of the first contacts penetrates a same number of the conductive layers.

18. The memory device according to claim 11, further comprising:
a second contact that extends along the first direction and includes a conductive member connected to the conductive layers via different PN junctions.

19. The memory device according to claim 18, wherein the second contact further includes:
a plurality of N-type semiconductor layers corresponding to the conductive layers, and
a P-type semiconductor layer provided on a side surface of the conductive member of the second contact and forming a PN junction with each of the N-type semiconductor layers.

20. The memory device according to claim 18, further comprising:
a sequencer configured to execute a read operation, wherein
the sequencer applies, to the second contact, a voltage that is equal to or less than a voltage applied to each of the conductive layers when reading data stored in the memory cell.
